(19) United States
(12) Patent Application Publication
(10) Pub. No.: US 2026/0121553 A1
(43) Pub. Date: Apr. 30, 2026

(54) DRIVE CIRCUIT, INVERTER, ELECTRONIC APPARATUS, AND VEHICLE

(71) Applicant: ROHM CO., LTD., Kyoto (JP)

(72) Inventor: Yu ENOMOTO, Kyoto (JP)

(21) Appl. No.: 19/366,652

(22) Filed: Oct. 23, 2025

(30) Foreign Application Priority Data
Oct. 30, 2024 (JP) 2024-190884

(51) Int. Cl. H02M 7/5387; H03K 17/687

(52) U.S. Cl. CPC H02M 7/53871; H03K 17/6871; H03K 2217/0063; H03K 2217/0072

(57) ABSTRACT

A drive circuit includes a high-side driver, a low-side driver, and a bootstrap circuit. The bootstrap circuit includes: a capacitance circuit configured to receive a power supply voltage and a reference voltage that is lower than the power supply voltage, to be charged according to the power supply voltage and the reference voltage, and to generate a drive voltage; and a pre-charge circuit configured to supply, based on an external signal, the reference voltage to the capacitance circuit when the high-side switch and the low-side switch are not driven, and not to supply the reference voltage to the capacitance circuit when the high-side switch and the low-side switch are driven.

### CROSS-REFERENCE TO RELATED APPLICATION

This application is based upon and claims the benefit of priority from Japanese Patent Application No. 2024-190884, filed on Oct. 30, 2024, the entire contents of which are incorporated herein by reference.

### TECHNICAL FIELD

The present disclosure relates to a signal transmission device, an electronic apparatus, and a vehicle.

### BACKGROUND

Conventionally, there is a drive circuit that drives an object to be driven by transmitting a pulse signal while isolating input and output from each other. This drive circuit is used in various applications (such as a power supply device and a motor drive device).

### BRIEF DESCRIPTION OF DRAWINGS

The accompanying drawings, which are incorporated in and constitute a part of the specification, illustrate embodiments of the present disclosure.

FIG. 1 is a diagram showing a basic configuration of a signal transmission device.

FIG. 2 is a diagram showing a basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view showing a layer in which a low-potential coil is formed in the semiconductor device of FIG. 3.

FIG. 6 is a plan view showing a layer in which a high-potential coil is formed in the semiconductor device of FIG. 3.

FIG. 7 is a cross-sectional view taken along line VIII-VIII shown in FIG. 6.

FIG. 8 is an enlarged view (showing an isolation structure) of a region XIII shown in FIG. 7.

FIG. 9 is a schematic diagram showing an example of a layout of a transformer chip.

FIG. 10 is a diagram showing a configuration of an inverter 700Y equipped with a drive circuit 500Y of a comparative example.

FIG. 11 is a diagram showing a configuration of a motor device 800 equipped with an inverter 700X according to the present disclosure.

FIG. 12 is a diagram showing a configuration of the inverter 700X equipped with a drive circuit 500X.

FIG. 13 is a view showing a vehicle A equipped with the motor device 800.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Signal Transmission Device (Basic Configuration)>

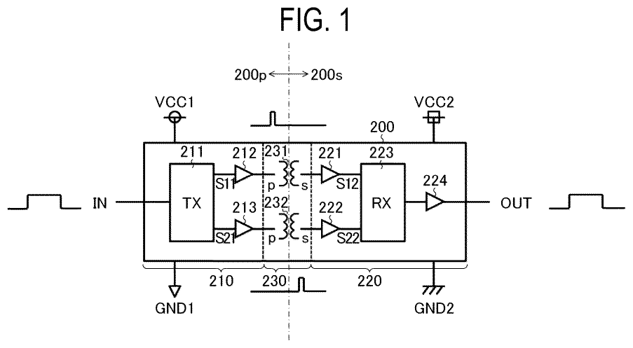

FIG. 1 is a view showing a basic configuration of a signal transmission device. A signal transmission device 200 of this configuration example is a semiconductor integrated circuit device (a so-called insulated gate driver IC) that insulates between a primary circuit system 200p (VCC1-GND1 system) and a secondary circuit system 200s (VCC2-GND2 system), transmits a pulse signal from the primary circuit system 200p to the secondary circuit system 200s, and drives a gate of a switch element (not shown) provided in the secondary circuit system 200s. For example, the signal transmission device 200 is formed by sealing a controller chip 210, a driver chip 220, and a transformer chip 230 in a single package.

The controller chip 210 is a semiconductor chip that operates by being supplied with a power supply voltage VCC1 (for example, a maximum of 7 V based on GND1). For example, a pulse transmitting circuit 211 and buffers 212 and 213 are integrated in the controller chip 210.

The pulse transmitting circuit 211 is a pulse generator that generates transmission pulse signals S11 and S21 in response to an input pulse signal IN. More specifically, when notifying that the input pulse signal IN is at a high level, the pulse transmitting circuit 211 pulse-drives the transmission pulse signal S11 (outputs a single-shot or multiple-shot transmission pulse). When notifying that the input pulse signal IN is at a low level, the pulse transmitting circuit 211 pulse-drives the transmission pulse signal S21. That is, the pulse transmitting circuit 211 pulse-drives one of the transmission pulse signals S11 and S21 according to a logic level of the input pulse signal IN.

The buffer 212 receives an input of the transmission pulse signal S11 from the pulse transmitting circuit 211 and pulse-drives the transformer chip 230 (specifically, a transformer 231).

The buffer 213 receives an input of the transmission pulse signal S21 from the pulse transmitting circuit 211 and pulse-drives the transformer chip 230 (specifically, a transformer 232).

The driver chip 220 is a semiconductor chip that operates by being supplied with a power supply voltage VCC2 (for example, a maximum of 30 V based on GND2). For example, buffers 221 and 222, a pulse receiving circuit 223, and a driver 224 are integrated in the driver chip 220.

The buffer 221 shapes a reception pulse signal S12 induced in the transformer chip 230 (specifically, the transformer 231) into a waveform and outputs it to the pulse receiving circuit 223.

The buffer 222 shapes a reception pulse signal S22 induced in the transformer chip 230 (specifically, the transformer 232) into a waveform and outputs it to the pulse receiving circuit 223.

The pulse receiving circuit 223 generates an output pulse signal OUT by driving the driver 224 in response to the reception pulse signals S12 and S22 input via the buffers 221 and 222, respectively. More specifically, the pulse receiving circuit 223 drives the driver 224 so as to raise the output pulse signal OUT to a high level in response to the pulse drive of the reception pulse signal S12 while lowering the output pulse signal OUT to a low level in response to the pulse drive of the reception pulse signal S22. That is, the pulse receiving circuit 223 switches a logic level of the output pulse signal OUT according to the logic level of the input pulse signal IN. As the pulse receiving circuit 223, for example, an RS flip-flop may be used.

The driver 224 generates the output pulse signal OUT based on a drive control by the pulse receiving circuit 223.

The transformer chip 230 uses the transformers 231 and 232 to provide DC insulation between the controller chip 210 and the driver chip 220, while outputting the transmission pulse signals S11 and S21 input from the pulse transmitting circuit 211, as the reception pulse signals S12 and S22, respectively, to the pulse receiving circuit 223. In the present disclosure, the phrase “DC insulation” means that an object to be insulated is not connected by a conductor.

More specifically, the transformer 231 outputs the reception pulse signal S12 from a secondary side coil 231s in response to the transmission pulse signal S11 input to a primary side coil 231p. On the other hand, the transformer 232 outputs the reception pulse signal S22 from a secondary side coil 232s in response to the transmission pulse signal S21 input to a primary side coil 232p.

As described above, due to characteristics of a spiral coil used for inter-insulation communication, the input pulse signal IN is separated into the two transmission pulse signals S11 and S21 (corresponding to a rise signal and a fall signal) and then transmitted from the primary circuit system 200p to the secondary circuit system 200s via the two transformers 231 and 232.

The signal transmission device 200 of this configuration example independently has a transformer chip 230 on which only the transformers 231 and 232 are mounted, separately from the controller chip 210 and the driver chip 220, and is formed by sealing these three chips in a single package.

With the configuration described above, both the controller chip 210 and the driver chip 220 can be formed by a general low-to-medium voltage process (breakdown voltage of several V to several tens of V), which eliminates a need to use a dedicated high-voltage process (breakdown voltage of several kV). Thus, it is possible to reduce manufacturing costs.

The signal transmission device 200 can be appropriately used, for example, as a power supply device or a motor drive device for in-vehicle equipment mounted in a vehicle. The vehicle includes an electric vehicle (xEV such as BEV [battery electric vehicle], HEV [hybrid electric vehicle], PHEV/PHV (plug-in hybrid electric vehicle/plug-in hybrid vehicle), or FCEV/FCV (fuel cell electric vehicle/fuel cell vehicle)) as well as an engine vehicle.

### <Transformer Chip (Basic Structure)>

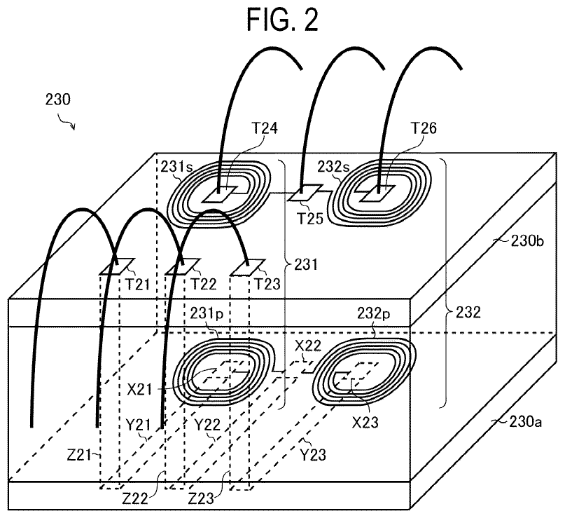

Next, a basic structure of the transformer chip 230 will be described. FIG. 2 is a view showing the basic structure of the transformer chip 230. In the transformer chip 230 of this figure, the transformer 231 includes the primary side coil 231p and the secondary side coil 231s facing each other in a vertical direction. The transformer 232 includes the primary side coil 232p and the secondary side coil 232s facing each other in the vertical direction.

The primary side coils 231p and 232p are both formed on a first wiring layer (lower layer in this FIG. 230a of the transformer chip 230. The secondary side coils 231s and 232s are both formed on a second wiring layer (upper layer in this FIG. 230b of the transformer chip 230. The secondary side coil 231s is disposed directly above the primary side coil 231p and faces the primary side coil 231p. Further, the secondary side coil 232s is disposed directly above the primary side coil 232p and faces the primary side coil 232p.

The primary side coil 231p is spirally laid so as to surround a periphery of an internal terminal X21 in a clockwise direction, with a first end as a start point connected to the internal terminal X21 and with a second end as an end point connected to an internal terminal X22. On the other hand, the primary side coil 232p is spirally laid so as to surround a periphery of an internal terminal X23 in a counterclockwise direction, with a first end as a start point connected to the internal terminal X23 and with a second end as an end point connected to the internal terminal X22. The internal terminals X21, X22, and X23 are arranged linearly in the order shown in the figure.

The internal terminal X21 is connected to an external terminal T21 of the second layer 230b via a conductive wiring Y21 and a via Z21. The internal terminal X22 is connected to an external terminal T22 of the second layer 230b via a conductive wiring Y22 and a via Z22. The internal terminal X23 is connected to an external terminal T23 of the second layer 230b via a conductive wiring Y23 and a via Z23. The external terminals T21 to T23 are arranged side by side in a line and used for wire-bonding with the controller chip 210.

The secondary side coil 231s is spirally laid so as to surround a periphery of an external terminal T24 in a counterclockwise direction, with a first end as a start point connected to the external terminal T24 and with a second end as an end point connected to an external terminal T25. On the other hand, the secondary side coil 232s is spirally laid so as to surround a periphery of an external terminal T26 in a clockwise direction, with a first end as a start point connected to the external terminal T26 and with a second end as an end point connected to the external terminal T25. The external terminals T24, T25, and T26 are arranged side by side in a line in the order shown in the figure and used for wire-bonding with the driver chip 220.

The secondary side coils 231s and 232s are AC-connected to the primary side coils 231p and 232p by magnetic coupling, respectively, and are DC-insulated from the primary side coils 231p and 232p. That is, the driver chip 220 is AC-connected to the controller chip 210 via the transformer chip 230 and is DC-insulated from the controller chip 210 by the transformer chip 230.

### <Transformer Chip (2-Channel Type)>

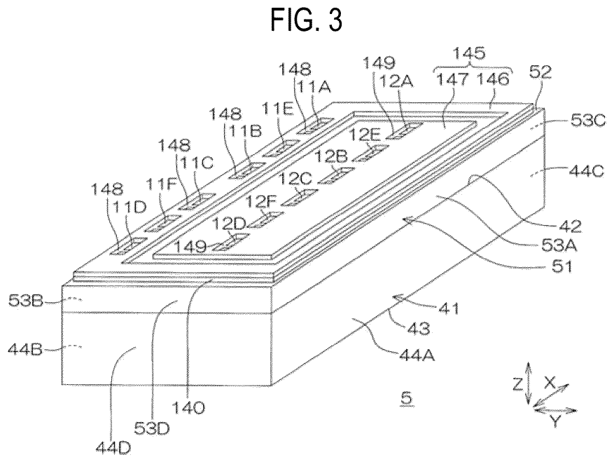

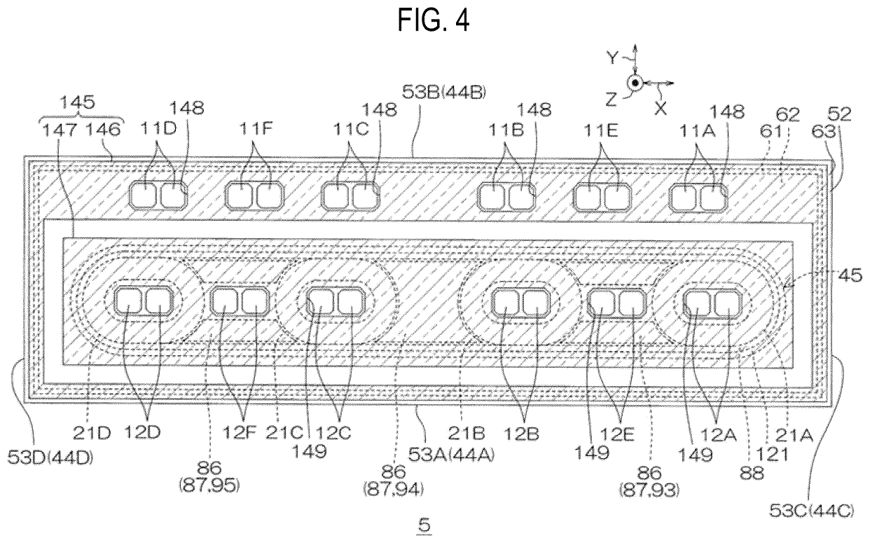

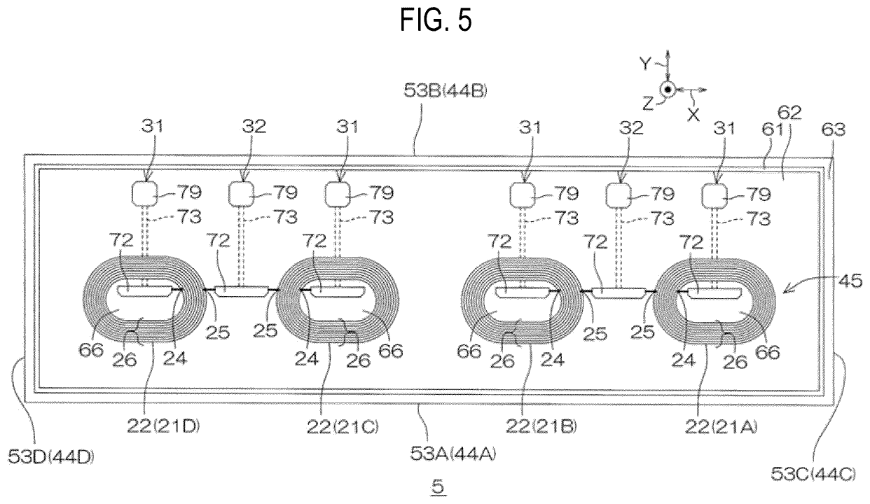

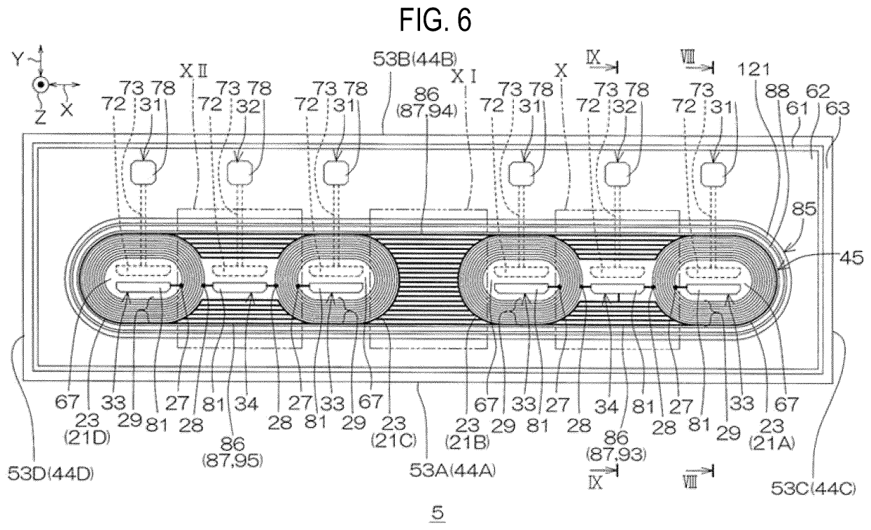

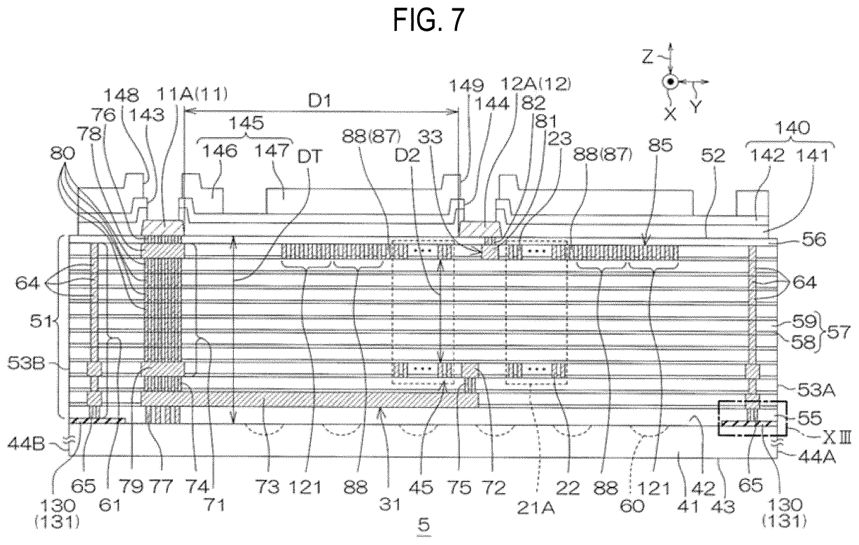

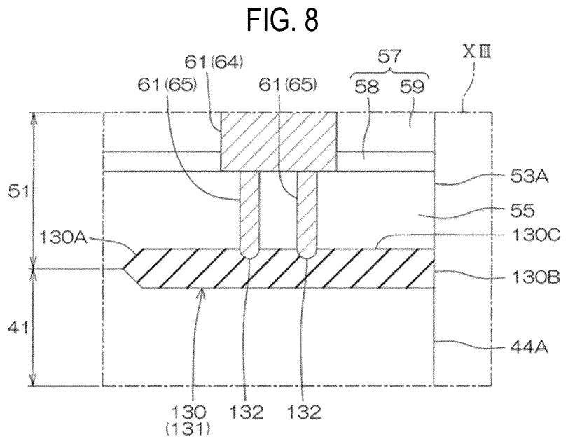

FIG. 3 is a perspective view showing a semiconductor device 5 used as a two-channel transformer chip. FIG. 4 is a plan view of the semiconductor device 5 shown in FIG. 3. FIG. 5 is a plan view showing a layer in which a low-potential coil 22 (corresponding to the primary side coil of a transformer) is formed in the semiconductor device 5 shown in FIG. 3. FIG. 6 is a plan view showing a layer in which a high-potential coil 23 (corresponding to the secondary side coil of the transformer) is formed in the semiconductor device 5 shown in FIG. 3. FIG. 7 is a cross-sectional view taken along line VIII-VIII shown in FIG. 6. FIG. 8 is an enlarged view of a region XIII shown in FIG. 7, and shows an isolation structure 130.

Referring to FIGS. 3 to 7, the semiconductor device 5 includes a semiconductor chip 41 having a rectangular parallelepiped shape. The semiconductor chip 41 includes at least one of silicon, a wide band gap semiconductor, or a compound semiconductor.

The wide band gap semiconductor is formed of a semiconductor that has a band gap exceeding a band gap of silicon (approximately 1.12 eV). The band gap of the wide band gap semiconductor may be 2.0 eV or more. The wide band gap semiconductor may be SiC (silicon carbide). The compound semiconductor may be a group III-V compound semiconductor. The compound semiconductor may include at least one of AlN (aluminum nitride), InN (indium nitride), GaN (gallium nitride), or GaAs (gallium arsenide).

In the present embodiment, the semiconductor chip 41 includes a semiconductor substrate made of silicon. The semiconductor chip 41 may be an epitaxial substrate having a stack structure including a semiconductor substrate made of silicon and an epitaxial layer made of silicon. A conductivity type of the semiconductor substrate may be an n-type or a p-type. The epitaxial layer may be an n-type or a p-type.

The semiconductor chip 41 has a first main surface 42 on one side, a second main surface 43 on the other side, and chip sidewalls 44A to 44D connecting the first main surface 42 and the second main surface 43. The first main surface 42 and the second main surface 43 are formed in a quadrangular shape (rectangular shape in the present embodiment) in a plan view as seen from their normal direction Z (hereinafter abbreviated as “in a plan view”).

The chip sidewalls 44A to 44D include a first chip sidewall 44A, a second chip sidewall 44B, a third chip sidewall 44C, and a fourth chip sidewall 44D. The first chip sidewall 44A and the second chip sidewall 44B form long sides of the semiconductor chip 41. The first chip sidewall 44A and the second chip sidewall 44B extend along a first direction X and face each other in a second direction Y. The third chip sidewall 44C and the fourth chip sidewall 44D form short sides of the semiconductor chip 41. The third chip sidewall 44C and the fourth chip sidewall 44D extend in the second direction Y and face each other in the first direction X. The chip sidewalls 44A to 44D are ground surfaces.

The semiconductor device 5 further includes an insulating layer 51 formed over the first main surface 42 of the semiconductor chip 41. The insulating layer 51 has an insulating main surface 52 and insulating sidewalls 53A to 53D. The insulating main surface 52 is formed in a quadrangular shape (rectangular shape in the present embodiment) matching the first main surface 42 in a plan view. The insulating main surface 52 extends parallel to the first main surface 42.

The insulating sidewalls 53A to 53D include a first insulating sidewall 53A, a second insulating sidewall 53B, a third insulating sidewall 53C, and a fourth insulating sidewall 53D. The insulating sidewalls 53A to 53D extend from a peripheral edge of the insulating main surface 52 toward the semiconductor chip 41 and are connected to the chip sidewalls 44A to 44D, respectively. Specifically, the insulating sidewalls 53A to 53D are formed flush with the chip sidewalls 44A to 44D, respectively. The insulating sidewalls 53A to 53D form ground surfaces flush with the chip sidewalls 44A to 44D, respectively.

The insulating layer 51 has a multi-layer insulating stack structure including a bottom insulating layer 55, a top insulating layer 56, and a plurality of (eleven layers in the present embodiment) interlayer insulating layers 57. The bottom insulating layer 55 is an insulating layer that directly covers the first main surface 42. The top insulating layer 56 is an insulating layer that forms the insulating main surface 52. The plurality of interlayer insulating layers 57 are insulating layers interposed between the bottom insulating layer 55 and the top insulating layer 56. In the present embodiment, the bottom insulating layer 55 has a single layer structure containing silicon oxide. In the present embodiment, the top insulating layer 56 has a single layer structure containing silicon oxide. Each of a thickness of the bottom insulating layer 55 and a thickness of the top insulating layer 56 may be 1 μm or more and 3 μm or less (for example, about 2 μm).

Each of the plurality of interlayer insulating layers 57 has a stack structure including a first insulating layer 58 on a side of the bottom insulating layer 55 and a second insulating layer 59 on a side of the top insulating layer 56. The first insulating layer 58 may contain silicon nitride. The first insulating layer 58 is formed as an etching stopper layer for the second insulating layer 59. A thickness of the first insulating layer 58 may be 0.1 μm or more and 1 μm or less (for example, about 0.3 μm).

The second insulating layer 59 is formed over the first insulating layer 58. The second insulating layer 59 contains an insulating material different from the first insulating layer 58. The second insulating layer 59 may contain silicon oxide. A thickness of the second insulating layer 59 may be 1 μm or more and 3 μm or less (for example, about 2 μm). The thickness of the second insulating layer 59 may exceed the thickness of the first insulating layer 58.

A total thickness DT of the insulating layer 51 may be 5 μm or more and 50 μm or less. The total thickness DT of the insulating layers 51 and the number of layers of the interlayer insulating layers 57 are arbitrary and are adjusted according to a dielectric breakdown voltage (dielectric breakdown tolerance) to be implemented. Insulating materials for the bottom insulating layer 55, the top insulating layer 56, and the interlayer insulating layers 57 are arbitrary and are not limited to specific insulating materials.

The semiconductor device 5 includes a first functional device 45 formed in the insulating layer 51. The first functional device 45 includes one or more (plurality of, in the present embodiment) transformers 21 (corresponding to the transformers described above). That is, the semiconductor device 5 is a multi-channel device including a plurality of transformers 21. The plurality of transformers 21 are formed in an inner portion of the insulating layer 51 with gaps from the insulating sidewalls 53A to 53D. The plurality of transformers 21 are formed with gaps from one another in the first direction X.

Specifically, the plurality of transformers 21 include a first transformer 21A, a second transformer 21B, a third transformer 21C, and a fourth transformer 21D, which are formed in this order from a side of the insulating sidewall 53C toward a side of the insulating sidewall 53D in a plan view. The plurality of transformers 21A to 21D have a same structure. The structure of the first transformer 21A will be described below as an example. Descriptions of the structures of the second transformer 21B, the third transformer 21C, and the fourth transformer 21D are omitted because the description of the structure of the first transformer 21A applies mutatis mutandis.

Referring to FIGS. 5 to 7, the first transformer 21A includes a low-potential coil 22 and a high-potential coil 23. The low-potential coil 22 is formed in the insulating layer 51. The high-potential coil 23 is formed in the insulating layer 51 so as to face the low-potential coil 22 in the normal direction Z. In the present embodiment, the low-potential coil 22 and the high-potential coil 23 are formed in a region sandwiched between the bottom insulating layer 55 and the top insulating layer 56 (that is, in the plurality of interlayer insulating layers 57).

The low-potential coil 22 is formed on a side of the bottom insulating layer 55 (the semiconductor chip 41) in the insulating layer 51, and the high-potential coil 23 is formed on a side of the top insulating layer 56 (the insulating main surface 52) in the insulating layer 51 with respect to the low-potential coil 22. That is, the high-potential coil 23 faces the semiconductor chip 41 with the low-potential coil 22 interposed therebetween. The low-potential coil 22 and the high-potential coil 23 may be disposed at any position. The high-potential coil 23 may also face the low-potential coil 22 with one or more interlayer insulating layers 57 interposed therebetween.

A distance between the low-potential coil 22 and the high-potential coil 23 (that is, the number of layers of the interlayer insulating layers 57) is appropriately adjusted according to a dielectric breakdown voltage and an electric field intensity between the low-potential coil 22 and the high-potential coil 23. In the present embodiment, the low-potential coil 22 is formed in the third interlayer insulating layer 57 counted from the side of the bottom insulating layer 55. In the present embodiment, the high-potential coil 23 is formed in the first interlayer insulating layer 57 counted from the side of the top insulating layer 56.

The low-potential coil 22 is embedded in the interlayer insulating layer 57 through the first insulating layer 58 and the second insulating layer 59. The low-potential coil 22 includes a first inner end 24, a first outer end 25, and a first spiral portion 26 spirally pulled around between the first inner end 24 and the first outer end 25. The first spiral portion 26 is pulled around in a spiral shape extending in an elliptical shape (oval shape) in a plan view. A portion forming an innermost peripheral edge of the first spiral portion 26 defines an elliptical first inner region 66 in a plan view.

The number of turns of the first spiral portion 26 may be five or more and thirty or less. A width of the first spiral portion 26 may be 0.1 μm or more and 5 μm or less. The width of the first spiral portion 26 may be 1 μm or more and 3 μm or less. The width of the first spiral portion 26 is defined by a width in a direction orthogonal to a spiral direction. A first winding pitch of the first spiral portion 26 may be 0.1 μm or more and 5 μm or less. The first winding pitch may be 1 μm or more and 3 μm or less. The first winding pitch is defined by a distance between two adjacent portions of the first spiral portion 26 in a direction orthogonal to the spiral direction.

A winding shape of the first spiral portion 26 and a planar shape of the first inner region 66 are arbitrary and are not limited to the shapes shown in FIG. 5 and the like. The first spiral portion 26 may be wound in a polygonal shape such as a triangular shape or a quadrangular shape, or a circular shape in a plan view. The first inner region 66 may be partitioned into a polygonal shape such as a triangular shape or a quadrangular shape, or a circular shape in a plan view according to the winding shape of the first spiral portion 26.

The low-potential coil 22 may contain at least one of titanium, titanium nitride, copper, aluminum, or tungsten. The low-potential coil 22 may have a stack structure including a barrier layer and a main body layer. The barrier layer defines a recess space in the interlayer insulating layer 57. The barrier layer may contain at least one of titanium or titanium nitride. The main body layer may contain at least one of copper, aluminum, or tungsten.

The high-potential coil 23 is embedded in the interlayer insulating layer 57 through the first insulating layer 58 and the second insulating layer 59. The high-potential coil 23 includes a second inner end 27, a second outer end 28, and a second spiral portion 29 spirally pulled around between the second inner end 27 and the second outer end 28. The second spiral portion 29 is pulled around in a spiral shape extending in an elliptical shape (oval shape) in a plan view. In the present embodiment, a portion forming an innermost peripheral edge of the second spiral portion 29 defines an elliptical second inner region 67 in a plan view. The second inner region 67 of the second spiral portion 29 faces the first inner region 66 of the first spiral portion 26 in the normal direction Z.

The number of turns of the second spiral portion 29 may be five or more and thirty or less. The number of turns of the second spiral portion 29 relative to the number of turns of the first spiral portion 26 is adjusted according to a voltage value to be boosted. The number of turns of the second spiral portion 29 may exceed the number of turns of the first spiral portion 26. Of course, the number of turns of the second spiral portion 29 may be less than the number of turns of the first spiral portion 26 or may be equal to the number of turns of the first spiral portion 26.

A width of the second spiral portion 29 may be 0.1 μm or more and 5 μm or less. The width of the second spiral portion 29 may be 1 μm or more and 3 μm or less. The width of the second spiral portion 29 is defined by a width in a direction orthogonal to a spiral direction. The width of the second spiral portion 29 may be equal to the width of the first spiral portion 26.

A second winding pitch of the second spiral portion 29 may be 0.1 μm or more and 5 μm or less. The second winding pitch may be 1 μm or more and 3 μm or less. The second winding pitch is defined by a distance between two adjacent portions of the second spiral portion 29 in a direction orthogonal to the spiral direction. The second winding pitch of the second spiral portion 29 may be equal to the first winding pitch of the first spiral portion 26.

A winding shape of the second spiral portion 29 and a planar shape of the second inner region 67 are arbitrary and are not limited to the shapes shown in FIG. 6 and the like. The second spiral portion 29 may be wound in a polygonal shape such as a triangular shape or a quadrangular shape, or a circular shape in a plan view. The second inner region 67 may be partitioned into a polygonal shape such as a triangular shape or a quadrangular shape, or a circular shape in a plan view according to the winding shape of the second spiral portion 29.

The high-potential coil 23 may be made of the same conductive material as the low-potential coil 22. That is, similar to the low-potential coil 22, the high-potential coil 23 may include a barrier layer and a main body layer.

Referring to FIG. 4, the semiconductor device 5 includes a plurality of (twelve in this figure) low-potential terminals 11 and a plurality of (twelve in this figure) high-potential terminals 12. The plurality of low-potential terminals 11 are electrically connected to the low-potential coils 22 of the corresponding transformers 21A to 21D, respectively. The plurality of high-potential terminals 12 are electrically connected to the high-potential coils 23 of the corresponding transformers 21A to 21D, respectively.

The plurality of low-potential terminals 11 are formed over the insulating main surface 52 of the insulating layer 51. Specifically, the plurality of low-potential terminals 11 are formed in a region on a side of the insulating sidewall 53B with gaps from the plurality of transformers 21A to 21D in the second direction Y, and are arranged with gaps from one another in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. In the present embodiment, the plurality of low-potential terminals 11A to 11F are each formed in pairs. The number of low-potential terminals 11A to 11F is arbitrary.

The first low-potential terminal 11A faces the first transformer 21A in the second direction Y in a plan view. The second low-potential terminal 11B faces the second transformer 21B in the second direction Y in a plan view. The third low-potential terminal 11C faces the third transformer 21C in the second direction Y in a plan view. The fourth low-potential terminal 11D faces the fourth transformer 21D in the second direction Y in a plan view. The fifth low-potential terminal 11E is formed in a region between the first low-potential terminal 11A and the second low-potential terminal 11B in a plan view. The sixth low-potential terminal 11F is formed in a region between the third low-potential terminal 11C and the fourth low-potential terminal 11D in a plan view.

The first low-potential terminal 11A is electrically connected to the first inner end 24 of the first transformer 21A (the low-potential coil 22). The second low-potential terminal 11B is electrically connected to the first inner end 24 of the second transformer 21B (the low-potential coil 22). The third low-potential terminal 11C is electrically connected to the first inner end 24 of the third transformer 21C (the low-potential coil 22). The fourth low-potential terminal 11D is electrically connected to the first inner end 24 of the fourth transformer 21D (the low-potential coil 22).

The fifth low-potential terminal 11E is electrically connected to the first outer end 25 of the first transformer 21A (the low-potential coil 22) and the first outer end 25 of the second transformer 21B (the low-potential coil 22). The sixth low-potential terminal 11F is electrically connected to the first outer end 25 of the third transformer 21C (the low-potential coil 22) and the first outer end 25 of the fourth transformer 21D (the low-potential coil 22).

The plurality of high-potential terminals 12 are formed over the insulating main surface 52 of the insulating layer 51 with gaps from the plurality of low-potential terminals 11. Specifically, the plurality of high-potential terminals 12 are formed in a region on a side of the insulating sidewall 53A with gaps from the plurality of low-potential terminals 11 in the second direction Y, and are arranged with gaps from one another in the first direction X.

The plurality of high-potential terminals 12 are formed in regions close to the corresponding transformers 21A to 21D, respectively, in a plan view. When the high-potential terminal 12 is close to the transformers 21A to 21D, it means that a distance between the high-potential terminal 12 and the transformer 21 is less than a distance between the low-potential terminal 11 and the high-potential terminal 12 in a plan view.

Specifically, the plurality of high-potential terminals 12 are formed with gaps from one another along the first direction X so as to face the plurality of transformers 21A to 21D along the first direction X in a plan view. More specifically, the plurality of high-potential terminals 12 are formed with gaps from one another along the first direction X so as to be located in the second inner region 67 of the high-potential coil 23 and in a region between adjacent high-potential coils 23 in a plan view. Thus, the plurality of high-potential terminals 12 are arranged side by side in a line with the plurality of transformers 21A to 21D in the first direction X in a plan view.

The plurality of high-potential terminals 12 includes a first high-potential terminal 12A, a second high-potential terminal 12B, a third high-potential terminal 12C, a fourth high-potential terminal 12D, a fifth high-potential terminal 12E, and a sixth high-potential terminal 12F. In the present embodiment, the plurality of high-potential terminals 12A to 12F are each formed in pairs. The number of high-potential terminals 12A to 12F is arbitrary.

The first high-potential terminal 12A is formed in the second inner region 67 of the first transformer 21A (the high-potential coil 23) in a plan view. The second high-potential terminal 12B is formed in the second inner region 67 of the second transformer 21B (the high-potential coil 23) in a plan view. The third high-potential terminal 12C is formed in the second inner region 67 of the third transformer 21C (the high-potential coil 23) in a plan view. The fourth high-potential terminal 12D is formed in the second inner region 67 of the fourth transformer 21D (the high-potential coil 23) in a plan view. The fifth high-potential terminal 12E is formed in a region between the first transformer 21A and the second transformer 21B in a plan view. The sixth high-potential terminal 12F is formed in a region between the third transformer 21C and the fourth transformer 21D in a plan view.

The first high-potential terminal 12A is electrically connected to the second inner end 27 of the first transformer 21A (the high-potential coil 23). The second high-potential terminal 12B is electrically connected to the second inner end 27 of the second transformer 21B (the high-potential coil 23). The third high-potential terminal 12C is electrically connected to the second inner end 27 of the third transformer 21C (the high-potential coil 23). The fourth high-potential terminal 12D is electrically connected to the second inner end 27 of the fourth transformer 21D (the high-potential coil 23).

The fifth high-potential terminal 12E is electrically connected to the second outer end 28 of the first transformer 21A (the high-potential coil 23) and the second outer end 28 of the second transformer 21B (the high-potential coil 23). The sixth high-potential terminal 12F is electrically connected to the second outer end 28 of the third transformer 21C (the high-potential coil 23) and the second outer end 28 of the fourth transformer 21D (the high-potential coil 23).

Referring to FIGS. 5 to 7, the semiconductor device 5 includes a first low-potential wiring 31, a second low-potential wiring 32, a first high-potential wiring 33, and a second high-potential wiring 34, which are formed in the insulating layer 51. In the present embodiment, a plurality of first low-potential wirings 31, a plurality of second low-potential wirings 32, a plurality of first high-potential wirings 33, and a plurality of second high-potential wirings 34 are formed.

The first low-potential wiring 31 and the second low-potential wiring 32 fix the low-potential coil 22 of the first transformer 21A and the low-potential coil 22 of the second transformer 21B to a same potential. Further, the first low-potential wiring 31 and the second low-potential wiring 32 fix the low-potential coil 22 of the third transformer 21C and the low-potential coil 22 of the fourth transformer 21D to a same potential. In the present embodiment, the first low-potential wirings 31 and the second low-potential wirings 32 fix all the low-potential coils 22 of the transformers 21A to 21D to a same potential.

The first high-potential wiring 33 and the second high-potential wiring 34 fix the high-potential coil 23 of the first transformer 21A and the high-potential coil 23 of the second transformer 21B to a same potential. Further, the first high-potential wiring 33 and the second high-potential wiring 34 fix the high-potential coil 23 of the third transformer 21C and the high-potential coil 23 of the fourth transformer 21D to a same potential. In the present embodiment, the first high-potential wirings 33 and the second high-potential wirings 34 fix all the high-potential coils 23 of the transformers 21A to 21D at a same potential.

The plurality of first low-potential wirings 31 are electrically connected to the corresponding low-potential terminals 11A to 11D and the first inner ends 24 of the corresponding transformers 21A to 21D (the low-potential coils 22), respectively. The plurality of first low-potential wirings 31 have a same structure. The structure of the first low-potential wiring 31 connected to the first low-potential terminal 11A and the first transformer 21A will be described below as an example. Description of structures of the other first low-potential wirings 31 will be omitted because the description of the structure of the first low-potential wiring 31 connected to the first transformer 21A applies mutatis mutandis.

The first low-potential wiring 31 includes a through-wiring 71, a low-potential connection wiring 72, a lead-out wiring 73, a first connection plug electrode 74, a second connection plug electrode 75, one or more (plurality of, in the present embodiment) pad plug electrodes 76, and one or more (plurality of, in the present embodiment) substrate plug electrodes 77.

The through-wiring 71, the low-potential connection wiring 72, the lead-out wiring 73, the first connection plug electrode 74, the second connection plug electrode 75, the pad plug electrodes 76, and the substrate plug electrodes 77 may be made of the same conductive material as the low-potential coil 22 and the like. That is, similar to the low-potential coil 22 and the like, each of the through-wiring 71, the low-potential connection wiring 72, the lead-out wiring 73, the first connection plug electrode 74, the second connection plug electrode 75, the pad plug electrodes 76, and the substrate plug electrodes 77 may include a barrier layer and a main body layer.

The through-wiring 71 penetrates the plurality of interlayer insulating layers 57 in the insulating layer 51 and extends in a columnar shape extending along the normal direction Z. In the present embodiment, the through-wiring 71 is formed in a region between the bottom insulating layer 55 and the top insulating layer 56 in the insulating layer 51. The through-wiring 71 has an upper end portion on a side of the top insulating layer 56 and a lower end portion on a side of the bottom insulating layer 55. The upper end portion of the through-wiring 71 is formed in the same interlayer insulating layer 57 as the high-potential coil 23, and is covered with the top insulating layer 56. The lower end of the through-wiring 71 is formed on the same interlayer insulating layer 57 as the low-potential coil 22.

In the present embodiment, the through-wiring 71 includes a first electrode layer 78, a second electrode layer 79, and a plurality of wiring plug electrodes 80. In the through-wiring 71, the first electrode layer 78, the second electrode layer 79, and the wiring plug electrodes 80 are made of the same conductive material as the low-potential coil 22 and the like. That is, similar to the low-potential coil 22 and the like, each of the first electrode layer 78, the second electrode layer 79, and the wiring plug electrodes 80 includes a barrier layer and a main body layer.

The first electrode layer 78 forms an upper end portion of the through-wiring 71. The second electrode layer 79 forms a lower end portion of the through-wiring 71. The first electrode layer 78 is formed in an island shape and faces the low-potential terminal 11 (the first low-potential terminal 11A) in the normal direction Z. The second electrode layer 79 is formed in an island shape and faces the first electrode layer 78 in the normal direction Z.

The plurality of wiring plug electrodes 80 are buried in the plurality of interlayer insulating layers 57 located between the first electrode layer 78 and the second electrode layer 79, respectively. The plurality of wiring plug electrodes 80 are stacked from the bottom insulating layer 55 toward the top insulating layer 56 so as to be electrically connected to one another, and electrically connect the first electrode layer 78 and the second electrode layer 79 to each other. Each of the plurality of wiring plug electrodes 80 has a plane area less than a plane area of the first electrode layer 78 and a plane area of the second electrode layer 79.

The number of layers of the plurality of wiring plug electrodes 80 is equal to the number of layers of the plurality of interlayer insulating layers 57. In the present embodiment, although six wiring plug electrodes 80 are buried in each interlayer insulating layer 57, the number of wiring plug electrodes 80 buried in each interlayer insulating layer 57 is arbitrary. Of course, one or more wiring plug electrodes 80 penetrating the plurality of interlayer insulating layers 57 may be formed.

The low-potential connection wiring 72 is formed in the first inner region 66 of the first transformer 21A (the low-potential coil 22) in the same interlayer insulating layer 57 as the low-potential coil 22. The low-potential connection wiring 72 is formed in an island shape and faces the high-potential terminal 12 (the first high-potential terminal 12A) in the normal direction Z. The low-potential connection wiring 72 may have a plane area exceeding the plane area of the wiring plug electrode 80. The low-potential connection wiring 72 is electrically connected to the first inner end 24 of the low-potential coil 22.

The lead-out wiring 73 is formed in a region between the semiconductor chip 41 and the through-wiring 71 in the interlayer insulating layer 57. In the present embodiment, the lead-out wiring 73 is formed in the first interlayer insulating layer 57 counted from the bottom insulating layer 55. The lead-out wiring 73 includes a first end portion on one side, a second end portion on the other side, and a wiring portion connecting the first end portion and the second end portion. The first end portion of the lead-out wiring 73 is located in a region between the semiconductor chip 41 and the lower end portion of the through-wiring 71. The second end portion of the lead-out wiring 73 is located in a region between the semiconductor chip 41 and the low-potential connection wiring 72. The wiring portion extends along the first main surface 42 of the semiconductor chip 41 and extends in a strip shape in a region between the first end portion and the second end portion.

The first connection plug electrode 74 is formed in a region between the through-wiring 71 and the lead-out wiring 73 in the interlayer insulating layer 57, and is electrically connected to the through-wiring 71 and the first end portion of the lead-out wiring 73. The second connection plug electrode 75 is formed in a region between the low-potential connection wiring 72 and the lead-out wiring 73 in the interlayer insulating layer 57, and is electrically connected to the low-potential connection wiring 72 and the second end portion of the lead-out wiring 73.

The plurality of pad plug electrodes 76 are formed in a region between the low-potential terminal 11 (the first low-potential terminal 11A) and the through-wiring 71 in the top insulating layer 56, and are electrically connected to the low-potential terminal 11 and the upper end portion of the through-wiring 71. The plurality of substrate plug electrodes 77 are formed in a region between the semiconductor chip 41 and the lead-out wiring 73 in the bottom insulating layer 55. In the present embodiment, the substrate plug electrodes 77 are formed in a region between the semiconductor chip 41 and the first end portion of the lead-out wirings 73, and are electrically connected to the semiconductor chip 41 and the first end portion of the lead-out wiring 73.

Referring to FIGS. 6 and 7, the plurality of first high-potential wirings 33 are electrically connected to the corresponding high-potential terminals 12A to 12D and the second inner ends 27 of the corresponding transformers 21A to 21D (the high-potential coils 23), respectively. The plurality of first high-potential wirings 33 have a same structure. A structure of the first high-potential wiring 33 connected to the first high-potential terminal 12A and the first transformer 21A will be described below as an example. Description of structures of the other first high-potential wirings 33 will be omitted because the description of the structure of the first high-potential wiring 33 connected to the first transformer 21A applies mutatis mutandis.

The first high-potential wiring 33 includes a high-potential connection wiring 81 and one or more (plurality of, in the present embodiment) pad plug electrodes 82. The high-potential connection wiring 81 and the pad plug electrodes 82 may be made of a same conductive material as the low-potential coil 22 and the like. That is, similar to the low-potential coil 22 and the like, the high-potential connection wiring 81 and the pad plug electrodes 82 may include a barrier layer and a main body layer.

The high-potential connection wiring 81 is formed in the second inner region 67 of the high-potential coil 23 in the same interlayer insulating layer 57 as the high-potential coil 23. The high-potential connection wiring 81 is formed in an island shape and faces the high-potential terminal 12 (the first high-potential terminal 12A) in the normal direction Z. The high-potential connection wiring 81 is electrically connected to the second inner end 27 of the high-potential coil 23. The high-potential connection wiring 81 is formed with a gap from the low-potential connection wiring 72 in a plan view and does not face the low-potential connection wiring 72 in the normal direction Z. Thus, an insulation distance between the low-potential connection wiring 72 and the high-potential connection wiring 81 increases, and the dielectric breakdown voltage of the insulation layer 51 increases accordingly.

The plurality of pad plug electrodes 82 are formed at a region between the high-potential terminal 12 (the first high-potential terminal 12A) and the high-potential connection wiring 81 in the top insulating layer 56, and are electrically connected to the high-potential terminal 12 and the high-potential connection wiring 81. Each of the plurality of pad plug electrodes 82 has a plane area smaller than a plane area of the high-potential connection wiring 81 in a plan view.

Referring to FIG. 7, a distance D1 between the low-potential terminal 11 and the high-potential terminal 12 may exceed a distance D2 between the low-potential coil 22 and the high-potential coil 23 (D2<D1). The distance D1 may exceed a total thickness DT of the plurality of interlayer insulating layers 57 (DT<D1). A ratio D2/D1 of the distance D2 to the distance D1 may be 0.01 or more and 0.1 or less. The distance D1 may be 100 μm or more and 500 μm or less. The distance D2 may be 1 μm or more and 50 μm or less. The distance D2 may be 5 μm or more and 25 μm or less. The values of the distance D1 and the distance D2 are arbitrary and are appropriately adjusted according to a dielectric breakdown voltage to be achieved.

Referring to FIGS. 6 and 7, the semiconductor device 5 includes a dummy pattern 85 buried in the insulating layer 51 so as to be located around the transformers 21A to 21D in a plan view.

The dummy pattern 85 is formed in a pattern (discontinuous pattern) different from those of the high-potential coil 23 and the low-potential coil 22 and is independent of the transformers 21A to 21D. In other words, the dummy pattern 85 does not function as the transformers 21A to 21D. The dummy pattern 85 is formed as a shield conductor layer that shields an electric field between the low-potential coil 22 and the high-potential coil 23 in the transformers 21A to 21D and suppresses electric field concentration on the high-potential coil 23. In the present embodiment, the dummy pattern 85 is pulled around with a line density equal to a line density of the high-potential coil 23 per unit area. The line density of the dummy pattern 85 being equal to the line density of the high-potential coil 23 means that the line density of the dummy pattern 85 falls within ±20% of the line density of the high-potential coil 23.

A depth position of the dummy pattern 85 in the insulating layer 51 is arbitrary and is adjusted according to an electric field intensity to be alleviated. The dummy pattern 85 may be formed in a region closer to the high-potential coil 23 than the low-potential coil 22 with respect to the normal direction Z. The dummy pattern 85 being closer to the high-potential coil 23 with respect to the normal direction Z means that a distance between the dummy pattern 85 and the high-potential coil 23 is less than a distance between the dummy pattern 85 and the low-potential coil 22 with respect to the normal direction Z.

In this case, the electric field concentration on the high-potential coil 23 can be appropriately suppressed. With respect to the normal direction Z, as the distance between the dummy pattern 85 and the high-potential coil 23 decreases, the electric field concentration on the high-potential coil 23 can be more effectively suppressed. The dummy pattern 85 may be formed in the same interlayer insulating layer 57 as the high-potential coil 23. In this case, the electric field concentration on the high-potential coil 23 can be suppressed more appropriately. The dummy pattern 85 includes a plurality of dummy patterns having different electrical states. The dummy pattern 85 may include a high-potential dummy pattern.

A depth position of a high-potential dummy pattern 86 in the insulating layer 51 is arbitrary and is adjusted according to the electric field intensity to be alleviated. The high-potential dummy pattern 86 may be formed in a region closer to the high-potential coil 23 than the low-potential coil 22 with respect to the normal direction Z. The high-potential dummy pattern 86 being closer to the high-potential coil 23 with respect to the normal direction Z means that a distance between the high-potential dummy pattern 86 and the high-potential coil 23 is less than a distance between the high-potential dummy pattern 86 and the low-potential coil 23 with respect to the normal direction Z2.

The dummy pattern 85 includes a floating dummy pattern formed in an electrically floating state in the insulating layer 51 so as to be located around the transformers 21A to 21D.

In the present embodiment, the floating dummy pattern is pulled around in a dense line shape so as to partially cover and partially expose a region around the high-potential coil 23 in a plan view. The floating dummy pattern may be formed in an ended shape, or may be formed in an endless shape.

A depth position of the floating dummy pattern in the insulating layer 51 is arbitrary and is adjusted according to the electric field intensity to be alleviated.

The number of floating lines is arbitrary and is adjusted according to the electric field to be alleviated. The floating dummy pattern may be formed by a plurality of floating lines.

Referring to FIG. 7, the semiconductor device 5 includes a second functional device 60 formed on the first main surface 42 of the semiconductor chip 41 in a device region 62. The second functional device 60 is formed by using a surface layer portion of the first main surface 42 of the semiconductor chip 41 and/or a region over the first main surface 42 of the semiconductor chip 41, and is covered with the insulating layer 51 (the bottom insulating layer 55). In FIG. 7, the second functional device 60 is simply indicated by a broken line shown in the surface layer portion of the first main surface 42.

The second functional device 60 is electrically connected to the low-potential terminal 11 via a low-potential wiring and is electrically connected to the high-potential terminal 12 via a high-potential wiring. The low-potential wiring has the same structure as the first low-potential wiring 31 (the second low-potential wiring 32) except that it is pulled around in the insulating layer 51 so as to be connected to the second functional device 60. The high-potential wiring has the same structure as the first high-potential wiring 33 (the second high-potential wiring 34) except that it is pulled around in the insulating layer 51 so as to be connected to the second functional device 60. Detailed description of the low-potential wiring and the high-potential wiring relating to the second functional device 60 will be omitted.

The second functional device 60 may include at least one of a passive device, a semiconductor rectifying device, or a semiconductor switching device. The second functional device 60 may include a circuit network in which any two or more among the passive device, the semiconductor rectifying device, and the semiconductor switching device are selectively combined. The circuit network may form a part or all of an integrated circuit.

The passive device may include a semiconductor passive device. The passive device may include one or both of a resistor and a capacitor. The semiconductor rectifying device may include at least one of a pn junction diode, a PIN diode, a Zener diode, a Schottky barrier diode, or a fast recovery diode. The semiconductor switching device may include at least one of a BJT [Bipolar Junction Transistor], a MISFET [Metal Insulator Field Effect Transistor], an IGBT [Insulated Gate Bipolar Junction Transistor], or a JFET [Junction Field Effect Transistor].

Referring to FIGS. 5 to 7, the semiconductor device 5 further includes a seal conductor 61 buried in the insulating layer 51. The seal conductor 61 is buried in the insulating layer 51 in a wall shape with gaps from the insulating sidewalls 53A to 53D in a plan view, and partitions the insulating layer 51 into the device region 62 and an outer region 63. The seal conductor 61 suppresses moisture and cracks from entering the device region 62 from the outer region 63.

The device region 62 is a region including the first functional device 45 (the plurality of transformers 21), the second functional device 60, the plurality of low-potential terminals 11, the plurality of high-potential terminals 12, the first low-potential wiring 31, the second low-potential wiring 32, the first high-potential wiring 33, the second high-potential wiring 34, and the dummy pattern 85. The outer region 63 is a region outside the device region 62.

The seal conductor 61 is electrically isolated from the device region 62. Specifically, the seal conductor 61 is electrically isolated from the first functional device 45 (the plurality of transformers 21), the second functional device 60, the plurality of low-potential terminals 11, the plurality of high-potential terminals 12, the first low-potential wiring 31, the second low-potential wiring 32, the first high-potential wiring 33, the second high-potential wiring 34, and the dummy pattern 85. More specifically, the seal conductor 61 is fixed in an electrically floating state. The seal conductor 61 does not form a current path leading to the device region 62.

The seal conductor 61 is formed in a strip shape along the insulating sidewalls 53 to 53D in a plan view. In the present embodiment, the seal conductor 61 is formed in a quadrangular annular shape (specifically, a rectangular annular shape) in a plan view. Thus, the seal conductor 61 defines the quadrangular (specifically, rectangular) device region 62 in a plan view. Further, the seal conductor 61 defines the quadrangular annular (specifically, rectangular annular) outer region 63 surrounding the device region 62 in a plan view.

Specifically, the seal conductor 61 has an upper end portion on a side of the insulating main surface 52, a lower end portion on a side of the semiconductor chip 41, and a wall portion extending in a wall shape between the upper end portion and the lower end portion. In the present embodiment, the upper end portion of the seal conductor 61 is formed with a gap from the insulating main surface 52 toward the semiconductor chip 41 and is located in the insulating layer 51. In the present embodiment, the upper end portion of the seal conductor 61 is covered with the top insulating layer 56. The upper end portion of the seal conductor 61 may be covered with one or more interlayer insulating layers 57. The upper end portion of the seal conductor 61 may be exposed from the top insulating layer 56. The lower end portion of the seal conductor 61 is formed with a gap from the semiconductor chip 41 toward the upper end portion.

As described above, in the present embodiment, the seal conductor 61 is buried in the insulating layer 51 so as to be located on a side of the semiconductor chip 41 with respect to the plurality of low-potential terminals 11 and the plurality of high-potential terminals 12. Further, the seal conductor 61 faces the first functional device 45 (the plurality of transformers 21), the first low-potential wiring 31, the second low-potential wiring 32, the first high-potential wiring 33, the second high-potential wiring 34, and the dummy pattern 85 in the insulating layer 51 in a direction parallel to the insulating main surface 52. The seal conductor 61 may face a portion of the second functional device 60 in the insulating layer 51 in a direction parallel to the insulating main surface 52.

The seal conductor 61 includes a plurality of seal plug conductors 64 and one or more (plurality of, in the present embodiment) seal via conductors 65. The number of seal via conductors 65 is arbitrary. An uppermost seal plug conductor 64 of the plurality of seal plug conductors 64 forms the upper end portion of the seal conductor 61. Each of the plurality of seal via conductors 65 forms the lower end portion of the seal conductor 61. The seal plug conductors 64 and the seal via conductors 65 may be made of the same conductive material as the low-potential coil 22. That is, similar to the low-potential coil 22 and the like, the seal plug conductors 64 and the seal via conductors 65 may include a barrier layer and a main body layer.

The plurality of seal plug conductors 64 are embedded in the plurality of interlayer insulating layers 57, respectively, and are formed in a quadrangular annular shape (specifically, a rectangular annular shape) surrounding the device region 62 in a plan view. The plurality of seal plug conductors 64 are stacked from the bottom insulating layer 55 toward the top insulating layer 56 so as to be connected to one another. The number of layers of the plurality of seal plug conductors 64 is equal to the number of layers of the plurality of interlayer insulating layers 57. Of course, one or more seal plug conductors 64 penetrating the plurality of interlayer insulating layers 57 may be formed.

When one annular seal conductor 61 is formed by an aggregation of the plurality of seal plug conductors 64, it is not necessary that all of the plurality of seal plug conductors 64 are formed to be annular. For example, at least one of the plurality of seal plug conductors 64 may be formed in an ended shape. Further, at least one of the plurality of seal plug conductors 64 may be divided into a plurality of ended stripe-shaped portions. However, considering the risk of moisture and cracks entering the device region 62, the plurality of seal plug conductors 64 may be formed in an endless shape (annular shape).

The plurality of seal via conductors 65 are formed at a region between the semiconductor chip 41 and the seal plug conductors 64 in the bottom insulating layer 55. The plurality of seal via conductors 65 are formed with gaps from the semiconductor chip 41 and are connected to the seal plug conductors 64. The plurality of seal via conductors 65 have a plane area less than a plane area of the seal plug conductors 64. When a single seal via conductor 65 is formed, the single seal via conductor 65 may have a plane area equal to or larger than the plane area of the seal plug conductors 64.

A width of the seal conductor 61 may be 0.1 μm or more and 10 μm or less. The width of the seal conductor 61 may be 1 μm or more and 5 μm or less. The width of the seal conductor 61 is defined by a width in a direction orthogonal to an extension direction of the seal conductor 61.

Referring to FIGS. 7 and 8, the semiconductor device 5 further includes the isolation structure 130, which is interposed between the semiconductor chip 41 and the seal conductor 61 and electrically isolates the seal conductor 61 from the semiconductor chip 41. The isolation structure 130 may include an insulator. In the present embodiment, the isolation structure 130 is constituted by a field insulating film 131 formed in the first main surface 42 of the semiconductor chip 41.

The field insulating film 131 includes at least one of an oxide film (silicon oxide film) or a nitride film (silicon nitride film). The field insulating film 131 may be formed of a LOCOS (local oxidation of silicon) film which is an example of an oxide film formed by oxidation of the first main surface 42 of the semiconductor chip 41. A thickness of the field insulating film 131 is arbitrary as long as it can insulate the semiconductor chip 41 and the seal conductor 61 from each other. The thickness of the field insulating film 131 may be 0.1 μm or more and 5 μm or less.

The isolation structure 130 is formed over the first main surface 42 of the semiconductor chip 41 and extends in a strip shape along the seal conductor 61 in a plan view. In the present embodiment, the isolation structure 130 is formed in a quadrangular annular shape (specifically, a rectangular annular shape) in a plan view. The isolation structure 130 has a connection portion 132 to which the lower end portion (the seal via conductor 65) of the seal conductor 61 is connected. The connection portion 132 may form an anchor portion in which the lower end portion (the seal via conductor 65) of the seal conductor 61 bites toward a side of the semiconductor chip 41. Of course, the connection portion 132 may be formed flush with a main surface of the isolation structure 130.

The isolation structure 130 includes an inner end portion 130A on a side of the device region 62, an outer end portion 130B on a side of the outer region 63, and a main body portion 130C between the inner end portion 130A and the outer end portion 130B. The inner end portion 130A defines a region in which the second functional device 60 (that is, the device region 62) is formed in a plan view. The inner end portion 130A may be formed integrally with an insulating film (not shown) formed over the first main surface 42 of the semiconductor chip 41.

The outer end portion 130B is exposed from the chip sidewalls 44A to 44D of the semiconductor chip 41 and is connected to the chip sidewalls 44A to 44D of the semiconductor chip 41. More specifically, the outer end portion 130B is formed flush with the chip sidewalls 44A to 44D of the semiconductor chip 41. The outer end portion 130B forms a flush ground surface between the chip sidewalls 44A to 44D of the semiconductor chip 41 and the insulating sidewalls 53A to 53D of the insulating layer 51. Of course, in another embodiment, the outer end portion 130B may be formed in the first main surface 42 with gaps from the chip sidewalls 44A to 44D.

The main body portion 130C has a flat surface extending substantially parallel to the first main surface 42 of the semiconductor chip 41. The main body portion 130C has the connection portion 132 to which the lower end portion (the seal via conductor 65) of the seal conductor 61 is connected. The connection portion 132 is formed in a portion of the main body portion 130C with gaps from the inner end portion 130A and the outer end portion 130B. The isolation structure 130 may take various forms other than the field insulating film 131.

Referring to FIG. 7, the semiconductor device 5 further includes an inorganic insulating layer 140 formed over the insulating main surface 52 of the insulating layer 51 so as to cover the seal conductor 61. The inorganic insulating layer 140 may be called a passivation layer. The inorganic insulating layer 140 protects the insulating layer 51 and the semiconductor chip 41 from above the insulating main surface 52.

In the present embodiment, the inorganic insulating layer 140 has a stack structure including a first inorganic insulating layer 141 and a second inorganic insulating layer 142. The first inorganic insulating layer 141 may contain silicon oxide. The first inorganic insulating layer 141 may contain USG (undoped silicate glass) which is impurity-free silicon oxide. A thickness of the first inorganic insulating layer 141 may be 50 nm or more and 5,000 nm or less. The second inorganic insulating layer 142 may contain silicon nitride. A thickness of the second inorganic insulating layer 142 may be 500 nm or more and 5,000 nm or less. By increasing a total thickness of the inorganic insulating layer 140, the dielectric breakdown voltage on the high-potential coil 23 can be increased.

When the first inorganic insulating layer 141 is made of USG and the second inorganic insulating layer 142 is made of silicon nitride, a dielectric breakdown voltage (V/cm) of USG exceeds a dielectric breakdown voltage (V/cm) of silicon nitride. Therefore, when the inorganic insulating layer 140 is thickened, the first inorganic insulating layer 141 may be made thicker than the second inorganic insulating layer 142.

The first inorganic insulating layer 141 may contain at least one of BPSG (boron doped phosphor silicate glass) or PSG (phosphorus silicate glass) as an example of silicon oxide. However, particularly in this case, since impurities (boron or phosphorus) are contained in silicon oxide, the first inorganic insulating layer 141 made of USG may be formed in order to increase the dielectric breakdown voltage on the high-potential coil 23. Of course, the inorganic insulating layer 140 may have a single layer structure formed by either the first inorganic insulating layer 141 or the second inorganic insulating layer 142.

The inorganic insulating layer 140 covers an entire region of the seal conductor 61, and has a plurality of low-potential pad openings 143 and a plurality of high-potential pad openings 144 formed outside the seal conductor 61. The plurality of low-potential pad openings 143 expose the plurality of low-potential terminals 11, respectively. The plurality of high-potential pad openings 144 expose the plurality of high-potential terminals 12, respectively. The inorganic insulating layer 140 may have an overlap portion positioned over a peripheral edge portion of the low-potential terminal 11. The inorganic insulating layer 140 may have an overlap portion positioned over a peripheral edge portion of the high-potential terminal 12.

The semiconductor device 5 further includes an organic insulating layer 145 formed over the inorganic insulating layer 140. The organic insulating layer 145 may contain a photosensitive resin. The organic insulating layer 145 may contain at least one of polyimide, polyamide, or polybenzoxazole. In the present embodiment, the organic insulating layer 145 contains polyimide. A thickness of the organic insulating layer 145 may be 1 μm or more and 50 μm or less.

The thickness of the organic insulating layer 145 may exceed the total thickness of the inorganic insulating layer 140. Further, a total thickness of the inorganic insulating layer 140 and the organic insulating layer 145 may be equal to or larger than the distance D2 between the low-potential coil 22 and the high-potential coil 23. In this case, the total thickness of the inorganic insulating layer 140 may be 2 μm or more and 10 μm or less. Further, the thickness of the organic insulating layer 145 may be 5 μm or more and 50 μm or less. With this structure, it is possible to suppress the inorganic insulating layer 140 and the organic insulating layer 145 from being thickened, and at the same time, it is possible to appropriately increase the dielectric breakdown voltage on the high-potential coil 23 by a stack film of the inorganic insulating layer 140 and the organic insulating layer 145.

The organic insulating layer 145 includes a first portion 146 covering a low-potential side region and a second portion 147 covering a high-potential side region. The first portion 146 covers the seal conductor 61 with the inorganic insulating layer 140 interposed therebetween. The first portion 146 has a plurality of low-potential terminal openings 148 exposing the plurality of low-potential terminals 11 (the low-potential pad openings 143), respectively, in a region outside the seal conductor 61. The first portion 146 may have an overlap portion positioned over a peripheral edge (overlap portion) of the low-potential pad opening 143.

The second portion 147 is formed with a gap from the first portion 146 and exposes the inorganic insulating layer 140 between the first portion 146 and the second portion 147. The second portion 147 has a plurality of high-potential terminal openings 149 exposing the plurality of high-potential terminals 12 (the high-potential pad openings 144), respectively. The second portion 147 may have an overlap portion positioned over a peripheral edge (overlap portion) of the high-potential pad opening 144.

The second portion 147 collectively covers the transformers 21A to 21D and the dummy pattern 85. Specifically, the second portion 147 collectively covers the plurality of high-potential coils 23, the plurality of high-potential terminals 12, the first high-potential dummy pattern 87, the second high-potential dummy pattern 88, and the floating dummy pattern 121.

The embodiment of the present disclosure may be implemented in other forms. In the above embodiment, an example in which the first functional device 45 and the second functional device 60 are formed has been described. However, a form having only the second functional device 60 without having the first functional device 45 may be adopted. In this case, the dummy pattern 85 may be removed. With this structure, the second functional device 60 can achieve the same effects as those described in the first embodiment (excluding the effects relating to the dummy pattern 85).

That is, when a voltage is applied to the second functional device 60 via the low-potential terminal 11 and the high-potential terminal 12, unwanted conduction between the high-potential terminal 12 and the seal conductor 61 can be suppressed. Further, when a voltage is applied to the second functional device 60 via the low-potential terminal 11 and the high-potential terminal 12, unwanted conduction between the low-potential terminal 11 and the seal conductor 61 can be suppressed.

Further, in the above embodiment, an example in which the second functional device 60 is formed has been described. However, the second functional device 60 is not necessarily required and may be removed.

Further, in the above embodiment, an example in which the dummy pattern 85 is formed has been described. However, the dummy pattern 85 is not necessarily required and may be removed.

Further, in the above embodiment, an example in which the first functional device 45 is of a multi-channel type including the plurality of transformers 21 has been described. However, a single-channel type first functional device 45 including a single transformer 21 may be employed.

### <Transformer Arrangement>

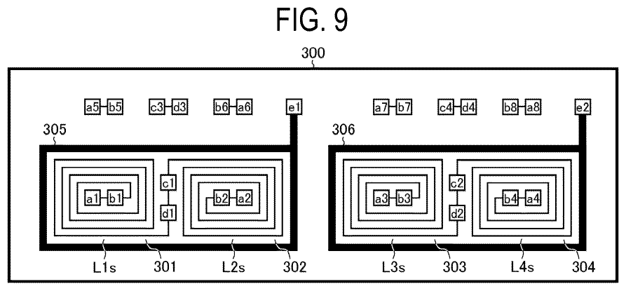

FIG. 9 is a plan view (top view) schematically showing an example of transformer arrangement in a two-channel type transformer chip 300 (corresponding to the above-described semiconductor device 5). The transformer chip 300 in this figure includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one end of a secondary side coil Lls forming the first transformer 301, and the pads c1 and d1 are connected to the other end of the secondary side coil Lls. The pads a2 and b2 are connected to one end of a secondary side coil L2s forming the second transformer 302, and the pads c1 and d1 are connected to the other end of the secondary side coil L2s.

Further, the pads a3 and b3 are connected to one end of a secondary side coil L3s forming the third transformer 303, and the pads c2 and d2 are connected to the other end of the secondary side coil L3s. The pads a4 and b4 are connected to one end of a secondary side coil L4s forming the fourth transformer 304, and the pads c2 and d2 are connected to the other end of the secondary side coil L4s.

A primary side coil forming the first transformer 301, a primary side coil forming the second transformer 302, a primary side coil forming the third transformer 303, and a primary side coil forming the fourth transformer 304 are not shown in this figure. However, the primary side coils have basically the same configurations as the secondary side coils L1s to L4s, respectively. The primary side coils are disposed directly below the secondary side coils L1s to L4s to face the secondary side coils L1s to L4s, respectively.

That is, the pads a5 and b5 are connected to one end of the primary side coil forming the first transformer 301, and the pads c3 and d3 are connected to the other end of the primary side coil of the first transformer 301. The pads a6 and b6 are connected to one end of the primary side coil forming the second transformer 302, and the pads c3 and d3 are connected to the other end of the primary side coil of the second transformer 302.

Further, the pads a7 and b7 are connected to one end of the primary side coil forming the third transformer 303, and the pads c4 and d4 are connected to the other end of the primary side coil of the third transformer 303. The pads a8 and b8 are connected to one end of the primary side coil forming the fourth transformer 304, and the pads c4 and d4 are connected to the other end of the primary side coil of the fourth transformer 304.

However, the pads a5 to a8, the pads b5 to b8, the pads c3 and c4, and the pads d3 and d4 are led out from an inside of the transformer chip 300 to a surface thereof through vias (not shown).

Among the plurality of pads, the pads a1 to a8 correspond to first current supply pads, respectively, and the pads b1 to b8 correspond to first voltage measurement pads, respectively. Further, the pads c1 to c4 correspond to second current supply pads, respectively, and the pads d1 to d4 correspond to second voltage measurement pads, respectively.

Thus, with the transformer chip 300 of this configuration example, a series resistance component of each coil can be accurately measured during an inspection for defective products. Therefore, in addition to rejecting defective products in which each coil is disconnected, it is possible to appropriately reject defective products in which a resistance value of each coil is abnormal (for example, a short circuit between coils), and further, it is possible to prevent defective products from being released to the market.

For the transformer chip 300 that has passed the defective product inspection, the plurality of pads may be used as means for connection with the primary side chip and the secondary side chip (for example, the controller chip 210 and the driver chip 220 described above).

Specifically, the pads a1 and b1, the pads a2 and b2, the pads a3 and b3, and the pads a4 and b4 may be connected to a signal input terminal or a signal output terminal of the secondary chip. Further, the pads c1 and d1 and the pads c2 and d2 may be connected to a common voltage application terminal (GND2) of the secondary chip.

On the other hand, the pads a5 and b5, the pads a6 and b6, the pads a7 and b7, and the pads a8 and b8 may be connected to a signal input terminal or a signal output terminal of the primary chip. Further, the pads c3 and d3 and the pads c4 and d4 may be connected to a common voltage application terminal (GND1) of the primary chip.

Here, as shown in FIG. 9, the first to fourth transformers 301 to 304 are coupled and arranged according to respective signal transmission directions thereof. Referring to this figure, for example, the first transformer 301 and the second transformer 302 that transmit signals from the primary chip to the secondary chip form a first pair by the first guard ring 305. Further, for example, the third transformer 303 and the fourth transformer 304 that transmit signals from the secondary chip to the primary chip form a second pair by the second guard ring 306.

The reason for the coupling described above is to ensure a breakdown voltage between a primary side coil and a secondary side coil when the primary side coil and the secondary side coil that form each of the first to fourth transformers 301 to 304 are stacked in the vertical direction of the substrate of the transformer chip 300. However, the first guard ring 305 and the second guard ring 306 are not necessarily essential components.

The first guard ring 305 and the second guard ring 306 may be connected to a low-impedance wiring such as a ground terminal via pads e1 and e2, respectively.

In the transformer chip 300, the pads c1 and d1 are shared between the secondary side coil L1s and the secondary side coil L2s. Further, the pads c2 and d2 are shared between the secondary side coil L3s and the secondary side coil L4s. Further, the pads c3 and d3 are shared between the primary side coil Llp and the primary side coil L2p. Further, the pads c4 and d4 are shared with the corresponding respective primary side coils. With this configuration, the number of pads can be reduced, and downsizing of the transformer chip 300 can be achieved.

Further, as shown in FIG. 9, the primary side coil and the secondary side coil that form each of the first to fourth transformers 301 to 304 may be wound in a rectangular shape (or a track shape with rounded corners) in a plan view of the transformer chip 300. With this configuration, an area of a portion where the primary side coil and the secondary side coil overlap with each other becomes large, and it is possible to improve transmission efficiency of the transformers.

Of course, the transformer arrangement in this figure is only an example, and the number, shape, and arrangement of coils and the arrangement of pads are arbitrary. Further, the chip structure, the transformer arrangement, and the like described above may be applied to general semiconductor devices in which coils are integrated on a semiconductor chip.

### <Regarding Drive Circuit 500Y>

Next, a signal transmission device 400, which corresponds to the above-described signal transmission device 200, will be described. The signal transmission device 400 can be used for both a drive circuit 500Y as a comparative example of the present disclosure and a drive circuit 500X of the present disclosure. First, the drive circuit 500Y will be described in detail. Subsequently, problems of the drive circuit 500Y will be described. Thereafter, the drive circuit 500X of the present disclosure will be described.

Below, voltages of a ground terminal GND1, a reference potential terminal GND2, and a reference potential terminal GND3 are referred to as a ground voltage GND1, a reference voltage GND2, and a reference voltage GND3, respectively, by using the same reference symbols. That is, the symbols GND1 to GND3 shown in the figure indicate contacts (nodes) and also indicate voltages of the contacts.

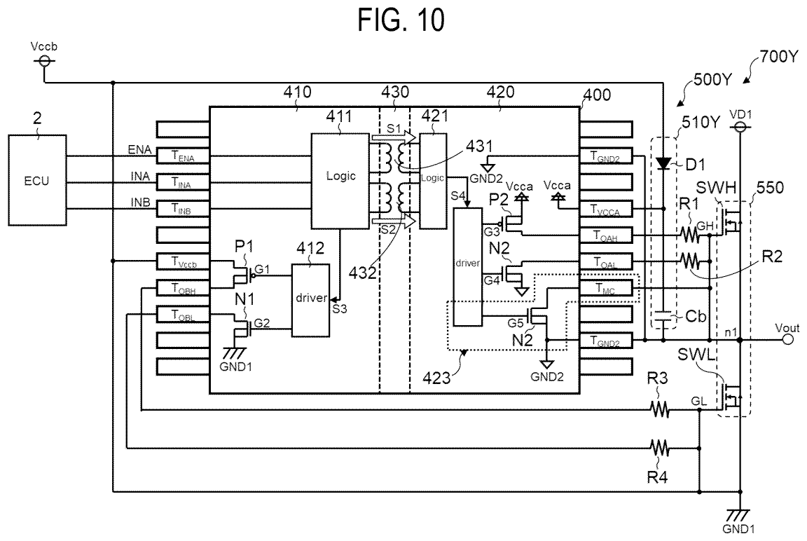

FIG. 10 is a diagram showing a configuration of an inverter 700Y equipped with the drive circuit 500Y of the comparative example. The drive circuit 500Y of this configuration example can be used for the inverter 700Y. The inverter 700Y is a type of motor drive device that drives a motor M by converting DC power supplied from an in-vehicle battery (not shown) into AC power. The motor M is a three-phase motor that is rotationally driven in response to three-phase drive voltages input from three-phase half-bridge output stages. Only one phase of the three-phase half-bridge output stages is shown in FIG. 10.

As shown in FIG. 10, the inverter 700Y includes the drive circuit 500Y and a switch output stage 550. The drive circuit 500Y operates by receiving a power supply voltage Vccb. When the drive circuit 500Y is started, the power supply voltage Vccb rises to an operating voltage of the drive circuit 500Y.

The drive circuit 500Y receives an enable signal ENA and input signals INA and INB from an ECU [Electronic Control Unit] 2. The drive circuit 500Y operates or stops according to a logic level of the enable signal ENA. The drive circuit 500Y generates drive voltages GH and GL based on the input signals INA and INB (more specifically, combination of logic levels of the input signals INA and INB). The drive circuit 500Y drives and controls the switch output stage 550 by using the drive voltages GH and GL.

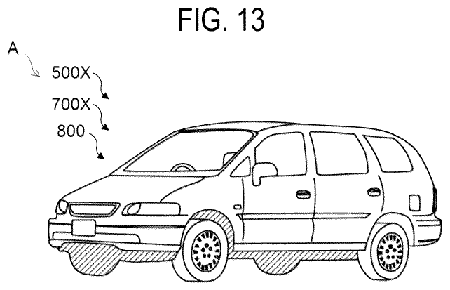

The ECU 2 is a means for performing overall electrical control for the drive circuit 500Y (the drive circuit 500X to be described later) and a vehicle A (see FIG. 13 to be described later) equipped with the drive circuit 500Y (the drive circuit 500X to be described later). The ECU 2 generates the enable signal ENA and the input signals INA and INB. The ECU 2 switches the logic levels of the enable signal ENA and the input signals INA and INB between high level and low level. The ECU 2 inputs the enable signal ENA and the input signals INA and INB to the drive circuit 500Y.

Specifically, when starting an operation of the drive circuit 500Y, the ECU 2 raises the enable signal ENA to a high level. Conversely, when stopping the operation of the drive circuit 500Y, the ECU 2 lowers the enable signal ENA to a low level.

The switch output stage 550 is connected between an application terminal of a motor drive voltage VD1 and the ground terminal GND1. The motor drive voltage VD1 is a DC voltage. The switch output stage 550 receives the motor drive voltage VD1 and the ground voltage GND1 and generates an AC output voltage Vout. Specifically, the switch output stage 550 pulse-drives the output voltage Vout between a high level (corresponding to the motor drive voltage VD1) and a low level (corresponding to the ground voltage GND1) by a switching operation to be described later.

The switch output stage 550 includes a high-side switch SWH and a low-side switch SWL. Each of the high-side switch SWH and the low-side switch SWL is an N-channel MOSFET. The high-side switch SWH and the low-side switch SWL are connected to each other to form a half-bridge output stage. Specifically, it is as follows.

A drain of the high-side switch SWH is connected to the application terminal of the motor drive voltage VD1. A source of the high-side switch SWH is connected to a drain of the low-side switch SWL. A source of the low-side switch SWL is connected to the ground terminal GND1. For convenience of description, a connection node between the source of the high-side switch SWH and the drain of the low-side switch SWL is referred to a node n1.

The drive voltage GH is input to a gate of the high-side switch SWH. The drive voltage GL is input to a gate of the low-side switch SWL. The high-side switch SWH is turned on and turned off according to the logic level of the drive voltage GH. The low-side switch SWL is turned on and turned off according to the logic level of the drive voltage GL. The output voltage Vout according to the on/off states of the high-side switch SWH and the low-side switch SWL is output from the node n1.

The high-side switch SWH and the low-side switch SWL are turned on and turned off complementarily according to the drive voltages GH and GL (and thus according to combination patterns of the logic levels of the input signals INA and INB). The term “complementarily” includes a case where the on/off states of the high-side switch SWH and the low-side switch SWL are completely reversed. The term “complementarily” also includes a case where a period during which the high-side switch SWH and the low-side switch SWL are simultaneously turned off (dead time) is provided.

### <Regarding Detailed Configuration of Drive Circuit 500Y>

The drive circuit 500Y also functions as a gate driver that controls gate voltages of the high-side switch SWH and the low-side switch SWL. The drive circuit 500Y has the signal transmission device 400, a plurality of discrete components (resistors R1 to R4), and a bootstrap circuit 510Y.

The signal transmission device 400 corresponds to the above-described signal transmission device 200. The signal transmission device 400 has external terminals (in this figure, external terminals T_{ENA}, T_{INA}, T_{INB}, T_{Vccb}, T_{OBH}, T_{OBL}, T_{GND1}, T_{GND2}, T_{Veca}, T_{OAH}, T_{OAL}, T_{MC}, and T_{GND2}) as means for communicating with the outside. The signal transmission device 400 generates the drive voltages GH and GL according to the input signals INA and INB. A detailed configuration of the signal transmission device 400 will be described later.

A first end of the resistor R1 is connected to the external terminal T^{OAH}. A first end of the resistor R2 is connected to the external terminal T_{OAL}. A second end of the resistor R2, together with a second end of the resistor R1, is connected to the switch output stage 550 (more specifically, to the gate of the high-side switch SWH, which will be described later, and to the node n1).

A first end of the resistor R3 is connected to the external terminal T_{OBH}. A first end of the resistor R4 is connected to the external terminal T_{OBL}. A second end of the resistor R4, together with a second end of the resistor R3, is connected to the switch output stage 550 (more specifically, to the gate of the low-side switch SWL, which will be described later, and to the ground terminal GND1).

The bootstrap circuit 510Y receives the power supply voltage Vccb and boosts the power supply voltage Vccb to generate a supply voltage Vcca. The bootstrap circuit 510Y will be described in detail.

The bootstrap circuit 510Y includes a diode D1 and a capacitor Cb. An anode of the diode D1 is connected to an application terminal of the power supply voltage Vccb. A cathode of the diode D1 is connected to the external terminal T_{veca} and a first terminal of the capacitor Cb. A second terminal of the capacitor Cb is connected to the node n1.

The bootstrap circuit 510Y is configured to charge the capacitor Cb by turning on and turning off the low-side switch SWL. Specifically, it is as follows. When the low-side switch SWL is turned on and the high-side switch SWH is turned off, a voltage of the node n1 is equivalent to the ground voltage GND1. Therefore, at this time, the capacitor Cb is charged by a potential difference between the power supply voltage Vccb and the ground voltage GND1.

As a charge amount of the capacitor Cb increases, a voltage of the first terminal of the capacitor Cb, and further a voltage of the external terminal T_{veca}, increase. This voltage of the external terminal T_{veca} is referred to as the power supply voltage Vcca. The power supply voltage Vcca is supplied to a high-side chip 420 via the external terminal T_{Veca}.

Here, the voltage of the node n1 is a midpoint voltage between the high-side switch SWH and the low-side switch SWL (=a voltage of the source of the high-side switch SWH). When the capacitor Cb is charged, the power supply voltage Vcca rises according to the charge amount of the capacitor Cb, with the voltage of the node n1 as a reference.

As described above, the bootstrap circuit 510Y generates the power supply voltage Vcca higher than the midpoint voltage (=the voltage of the node n1) and supplies the power supply voltage Vcca to the signal transmission device 400 (more specifically, the high-side chip 420).

The high-side chip 420 operates by receiving the power supply voltage Vcca. In other words, the bootstrap circuit 510Y can also be considered as a power supply circuit for operating the high-side chip 420.

Specifically, the high-side chip 420 uses the power supply voltage Vcca to perform an on/off control of the high-side switch SWH. More specifically, the high-side chip 420 pulse-drives the drive voltage GH between a high level (corresponding to the power supply voltage Vcca) and a low level (corresponding to the reference voltage GND1).

When the drive voltage GH is at a high level (corresponding to the power supply voltage Vcca), a difference voltage between the node n1 and the power supply voltage Vcca exceeds an on-threshold voltage of the high-side switch SWH. This causes the high-side switch SWH to be turned on. Conversely, when the drive voltage GH is at a low level (corresponding to the ground voltage GND1), the difference voltage between the node n1 and the power supply voltage Vcca falls below the on-threshold voltage of the high-side switch SWH. This causes the high-side switch SWH to be turned off.

### <Regarding Detailed Configuration of Signal Transmission Device 400>

The configuration of the signal transmission device 400 will be described in more detail. The signal transmission device 400 includes a low-side chip 410, the high-side chip 420, and a transformer chip 430. The signal transmission device 400 is a semiconductor integrated circuit device that is configured by sealing the low-side chip 410, the high-side chip 420, and the transformer chip 430 in one package.

The low-side chip 410 operates by receiving the power supply voltage Vccb via the external terminal T_{Vecb}. The low-side chip 410 receives the enable signal ENA via the external terminal T_{ENA}. The low-side chip 410 also receives the input signal INA via the external terminal T_{INA}. The low-side chip 410 also receives the input signal INB via the external terminal T_{INB}.

When the input enable signal ENA is at a high level, the low-side chip 410 generates a control signal S1 and the drive voltage GL based on the input signals INA and INB. At this time, the low-side chip 410 transmits the generated control signal S1 to the high-side chip 420 via the transformer chip 430. The low-side chip 410 also inputs the generated drive voltage GL to the gate of the low-side switch SWL to drive and control the low-side switch SWL.

Details of the low-side chip 410 are as follows. The low-side chip 410 includes a logic circuit 411, a driver 412, a switch element P1, and a switch element N1.

When the enable signal ENA is at a high level, the logic circuit 411 generates control signals S1 to S3 in response to the input signals INA and INB. The logic circuit 411 inputs the control signals S1 and S2 to the transformer chip 430 (more specifically, transformers 431 and 432 to be described later). The logic circuit 411 inputs the control signal S3 to the driver 412.

The driver 412 generates drive signals G1 and G2 in response to the logic level of the control signal S3. The driver 412 inputs the generated drive signal G1 to a gate of the switch element P1 to drive and control the switch element P1. The driver 412 also inputs the generated drive signal G2 to a gate of the switch element N1 to drive and control the switch element N1.

The switch element P1 is a P-channel type MOSFET. A source of the switch element P1 is connected to the application terminal of the power supply voltage Vccb via the external terminal Tvech. A drain of the switch element P1 is connected to the first end of the resistor R3 via the external terminal T_{OBH}.

The switch element N1 is an N-channel type MOSFET. A source of the switch element N1 is connected to the ground terminal GND1. A drain of the switch element N1 is connected to the first end of the resistor R4 via the external terminal TOBI.

The second end of the resistor R4, together with the second end of the resistor R3, is connected to the gate of the low-side switch SWL and the ground terminal GND1.

When the switch element P1 is in an on state, the power supply voltage Vccb is output from the external terminal T_{OBH}. In addition, when the switch element N1 is in an on state, the ground voltage GND1 is output from the external terminal TOBI.

The driver 412 drives and controls the switch elements P1 and N1 as follows to turn on and turn off the low-side switch SWL. For example, when the low-side switch SWL is turned on, the switch element P1 is turned on and the switch element N1 is turned off. Thus, as described above, the power supply voltage Vccb is output from the external terminal T_{OBH}. At this time, since the switch element N1 is turned off, the ground voltage GND1 is not output from the external terminal T_{OBL}. As a result, a high-level drive voltage GL (a voltage based on the power supply voltage Vccb) is generated at a connection node (i.e., the gate terminal of the low-side switch SWL) between the resistors R3 and R4.

Conversely, when the low-side switch SWL is turned off, the switch element P1 is turned off and the switch element N1 is turned on. Thus, as described above, the ground voltage GND1 is output from the external terminal T_{OBL}. At this time, since the switch element P1 is turned off, the power supply voltage Vccb is not output from the external terminal T_{OBH}. As a result, a low-level drive voltage GL (a voltage based on the ground voltage GND1) is generated at the connection node (i.e., the gate terminal of the low-side switch SWL) between the resistors R3 and R4.

The transformer chip 430 has a plurality of transformers (in this figure, the transformers 431 and 432). Each of the transformers 431 and 432 has a primary winding and a secondary winding.

The primary windings of the transformers 431 and 432 are connected to the low-side chip 410 (more specifically, the logic circuit 411). The secondary windings of the transformers 431 and 432 are connected to the high-side chip 420 (more specifically, a logic circuit 421 which will be described later). Each of the transformers 431 and 432 establishes transmission and reception of signals between the low-side chip 410 and the high-side chip 420 via the primary winding and the secondary winding while providing DC insulation between the low-side chip 410 and the high-side chip 420.

The control signal S1 input to the primary winding of the transformer 431 and the control signal S2 input to the primary winding of the transformer 432 are transmitted to the secondary windings and input to the high-side chip 420 (more specifically, the logic circuit 421).

The high-side chip 420 receives the control signals S1 and S2 via the transformer chip 430 as described above. The high-side chip 420 generates the drive voltage GH based on the input control signals S1 and S2. Further, the high-side chip 420 inputs the drive voltage GH to the gate of the high-side switch SWH. The details of the high-side chip 420 are as follows.

The high-side chip 420 includes the logic circuit 421, a driver 422, a switch element P2, and switch elements N2 and N3.

The logic circuit 421 receives the control signals S1 and S2. The logic circuit 421 generates a control signal S4 based on the control signals S1 and S2. The logic circuit 421 inputs the control signal S4 to the driver 422.

The driver 422 generates drive signals G3 to G5 based on the input control signal S4. The driver 422 inputs the drive signal G3 to a gate of the switch element P2 to drive and control the switch element P2. The driver 422 also inputs the drive signal G4 to a gate of the switch element N2 to drive and control the switch element N2. The driver 422 also inputs the drive signal G5 to a gate of the switch element N3 to drive and control the switch element N3.

The switch element P2 is a P-channel type MOSFET. A source of the switch element P2 is connected to an application terminal of the power supply voltage Vcca. A drain of the switch element P2 is connected to the first end of the resistor R1 via the external terminal T_{OAH}.

The switch element N2 is an N-channel type MOSFET. A source of the switch element N2 is connected to the reference potential terminal GND2. A drain of the switch element N2 is connected to the first end of the resistor R2 via the external terminal T_{OAL}.

When the switch element P2 is in an on state, the power supply voltage Vcca is output from the external terminal T_{OAH}. In addition, when the switch element N2 is in an on state, the reference voltage GND2 is output from the external terminal T_{OAL}.

The driver 422 drives and controls the switch elements P2 and N2 as follows to perform an on/off control of the high-side switch SWH. When the high-side switch SWH is turned on, the switch element P2 is turned on and the switch element N2 is turned off. Thus, as described above, the power supply voltage Vcca is output from the external terminal T_{OAH}. As a result, a high-level drive voltage GH (a voltage based on the power supply voltage Vcca) is supplied to the gate terminal of the high-side switch SWH via the resistor R1.

As described above, the power supply voltage Vcca is higher than the voltage of the node n1 (the source voltage of the high-side switch SWH). Therefore, at this time, a gate-source voltage (a voltage difference between the voltage of the node n1 and the power supply voltage Vcca) exceeds the on-threshold voltage of the high-side switch SWH, and the high-side switch SWH is turned on.

Conversely, when the high-side switch SWH is turned off, the switch element P2 is turned off and the switch element N2 is turned on. Thus, as described above, the reference voltage GND2 is output from the external terminal T_{OAL}. As a result, a low-level drive voltage GH (a voltage based on the reference voltage GND2) is supplied to the gate terminal of the high-side switch SWH via the resistor R2. Therefore, at this time, the gate-source voltage (the voltage difference between the voltage of the node n1 and the power supply voltage Vcca) falls below the on-threshold voltage of the high-side switch SWH, and the high-side switch SWH is turned off.

### <Regarding Mirror Clamp Circuit 423>

The switch element N3 and the driver 422 constitute a mirror clamp circuit 423. Here, the mirror clamp circuit 423 will be described. The switch element N3 is an N-channel type MOSFET. A source of the switch element N3 is connected to the node n1 via the external terminal T_{MC}. A drain of the switch element N3 is connected to the reference potential terminal GND2.

The mirror clamp circuit 423 suppresses the high-side switch SWH from being erroneously turned-on. That is, in order to prevent the gate voltage of the high-side switch SWH from rising unintentionally, the mirror clamp circuit 423 forcibly lowers the gate voltage of the high-side switch SWH to an arbitrary value (for example, 0 V) at a predetermined timing.

The above-mentioned “erroneously turned-on” may occur, for example, when the high-side switch SWH and the low-side switch SWL are SiC-MOSFETs. In SiC-MOSFETs, ringing may occur in a gate voltage or the gate voltage may rise when transitioning (switching) between an on state and an off state. This rise may cause the high-side switch SWH to be self-turned-on (erroneously turned-on). Further, the rise of the gate voltage is not limited to SiC-MOSFETs and may occur in other types of switch elements.

According to the mirror clamp circuit 423, the gate voltage of the high-side switch SWH is forcibly lowered to an arbitrary value (for example, 0 V) at a predetermined timing as described above. Specifically, the logic circuit 411 raises the drive signal G5 to a high level at an off timing of the high-side switch SWH to turn on the switch element N3. Therefore, at the off timing of the high-side switch SWH, the gate voltage of the high-side switch SWH is forcibly lowered below the on-threshold value (specifically, the reference voltage GND2). As described above, the mirror clamp circuit 423 suppresses the high-side switch SWH from being erroneously turned-on.

### <Considerations on Mirror Clamp Circuit 423>

As described above, the high-side chip 420 operates by receiving the power supply voltage Vcca generated by the bootstrap circuit 510Y. Here, the charge amount of the capacitor Cb is not sufficiently high for a certain period from the start of the drive circuit 500Y. Therefore, during this period, the power supply voltage Vcca is low, and the high-side chip 420 may not operate normally.

In other words, the mirror clamp circuit 423 may not function as described above. Specifically, the switch element N3 may not be turned on at the off timing of the high-side switch SWH. Thus, during this period, the gate voltage (the drive voltage GH) of the high-side switch SWH cannot be prevented from rising as described above. Therefore, during this period, the high-side switch SWH may be unintentionally self-turned-on (erroneously turned-on).

To address the problem described above, the drive circuit 500X of the present disclosure is capable of preventing the high-side switch SWH from being self-turned-on as described above. The drive circuit 500X according to the embodiment of the present disclosure will be described in detail below. The drive circuit 500X according to the embodiment of the present disclosure includes a configuration common to the above-described drive circuit 500Y. Therefore, the common configuration is denoted by the same reference numerals, and explanation thereof will be omitted.

### <Regarding Drive Circuit 500X According to Embodiment of Present Disclosure>

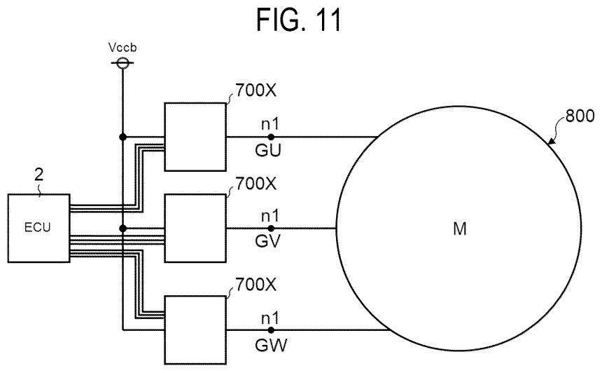

FIG. 11 is a diagram showing a configuration of a motor device 800 equipped with an inverter 700X according to the present disclosure. The drive circuit 500X of this configuration example can be used for the inverter 700X. The inverter 700X is a type of motor drive device that drives a motor M by converting DC power supplied from an in-vehicle battery (not shown) into AC power.

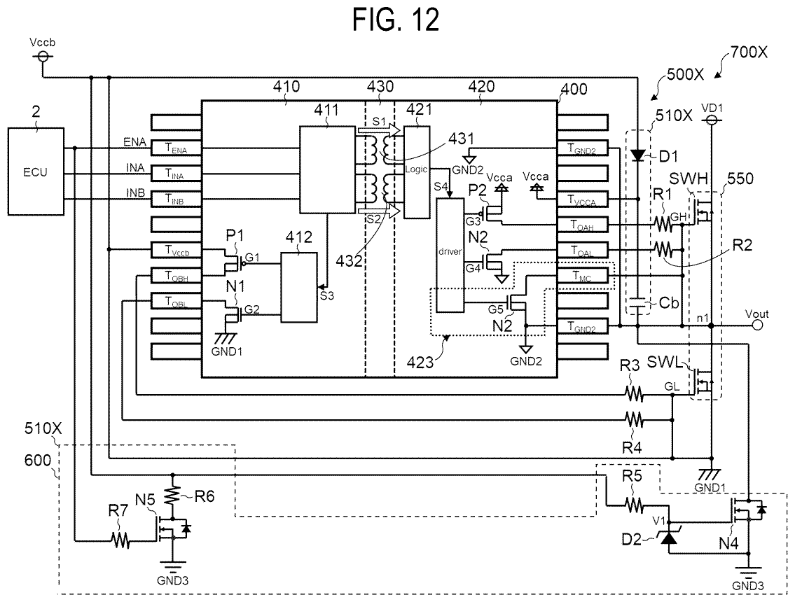

As shown in FIG. 11, the motor M is a three-phase motor that is rotated and driven according to three-phase drive voltages input from three-phase half-bridge output stages. The motor M is a three-phase motor that is rotationally driven in response to three-phase drive voltages GU/GV/GW (each of which corresponds to the output voltage Vout in FIG. 12, which will be described later) input from three-phase half-bridge output stages. The motor M is mounted on the motor device 800. The motor device 800 is configured to drive the motor M by using the three-phase inverter 700X.

FIG. 12 is a diagram showing a configuration of the inverter 700X equipped with the drive circuit 500X. Further, FIG. 12 shows the inverter 700X, which corresponds to one phase of the three-phase half-bridge output stages.

As shown in FIG. 12, the inverter 700X includes the same switch output stage 550 as that described above. In addition, the inverter 700X includes the drive circuit 500X. The drive circuit 500X operates by receiving the power supply voltage Vccb. When the drive circuit 500X is started, the power supply voltage Vccb rises to an operating voltage of the drive circuit 500X.

The drive circuit 500X receives the enable signal ENA and the input signals INA and INB from the ECU [Electronic Control Unit] 2. The drive circuit 500X operates or stops according to the logic level of the enable signal ENA. The drive circuit 500X generates the drive voltages GH and GL based on the input signals INA and INB (more specifically, combinations of the logic levels of the input signals INA and INB). The drive circuit 500X drives and controls the switch output stage 550 by using the drive voltages GH and GL.

In the case shown in FIG. 11, the switch output stage 550 of each inverter 700X is a three-phase (U-phase/V-phase/W-phase) half-bridge output stage. Each switch output stage 550 generates the three-phase output voltage Vout (the drive voltages GU/GV/GW in FIG. 11) and outputs it from each node n1. The motor M is driven by receiving the three-phase drive voltages GU/GV/GW.

### <Regarding Detailed Configuration of Drive Circuit 500X>

The drive circuit 500X includes the same signal transmission device 400 as that described above, and predetermined discrete components (in this figure, the resistors R1 to R4). In addition, the drive circuit 500X includes a bootstrap circuit 510X.

The bootstrap circuit 510X corresponds to the above-described bootstrap circuit 510Y. That is, the bootstrap circuit 510X includes the same diode D1 and capacitor Cb as those described above. On the other hand, the bootstrap circuit 510X is different from the bootstrap circuit 510Y in that the former includes a pre-charge circuit 600.

The pre-charge circuit 600 includes switch elements N4 and N5, resistors R5 to R7, and a Zener diode D2.

Each of the switch elements N4 and N5 is an N-channel type MOSFET. A drain of the switch element N4 is connected to the second terminal of the capacitor Cb. A gate of the switch element N4 is connected to a first end of the resistor R5 and to a cathode of the Zener diode D2. A source of the switch element N4 is connected to the reference potential terminal GND3 and to the cathode of the Zener diode D2.

A drain of the switch element N5 is connected to a first end of the resistor R6. A gate of the switch element N5 is connected to a first end of the resistor R7. A source of the switch element N5 is connected to the reference potential terminal GND3.

A second end of the resistor R5, together with a second end of the resistor R6, is connected to the application terminal of the power supply voltage Vccb. A second end of the resistor R7, together with the external terminal T_{ENA}, is connected to an output terminal (the ECU 2) of the enable signal ENA. At a connection node (the gate of the switch element N4) between the resistor R5 and the Zener diode D2, a voltage V1 is generated by dividing the power supply voltage Vccb by the resistor R5 and the Zener diode D2.

### <Regarding Charging Capacitor Cb>

Next, an operation of the bootstrap circuit 510X (particularly, charging of the capacitor Cb) will be described. First, when the drive circuit 500X is started, the power supply voltage Vccb rises to a predetermined voltage value (the operating voltage of the drive circuit 500X). At this time, the ECU 2 maintains the enable signal ENA at a low level. For this reason, the signal transmission device 400 does not start operating. In addition, at this time, the gate voltage of the switch element N5 is less than an on-threshold voltage of the switch element N5. Therefore, the switch element N5 is turned off.

At this time, as the power supply voltage Vccb rises, the voltage V1 rises. When the voltage V1 rises and exceeds an on-threshold voltage of the switch element N4, the switch element N4 is turned on. In other words, a source-drain of the switch element N4 is brought into a conductive state. Thus, the power supply voltage Vccb is applied to the first terminal of the capacitor Cb, and the reference voltage GND3 is applied to the second terminal of the capacitor Cb. Therefore, the capacitor Cb is charged by a voltage difference between the power supply voltage Vccb and the reference voltage GND3.

When the capacitor Cb is sufficiently charged, the ECU 2 raises the enable signal ENA to a high level. The expression of “the capacitor Cb is sufficiently charged” can be interpreted as the power supply voltage Vcca reaching a voltage value that can start up the mirror clamp circuit 423 (specifically, a voltage value that can perform an on/off control of the switch element N3).

When the enable signal ENA rises to the high level, the signal transmission device 400 is started. At this time, the gate voltage of the switch element N5 (the enable signal ENA supplied from the ECU 2 via the resistor R7) exceeds the on-threshold voltage of the switch element N5. Thus, the switch element N5 is turned on.

When the switch element N5 is turned on, the gate of the switch element N4 has the same potential as the reference potential terminal GND3 via the resistors R5 and R6 and the switch element N5. That is, at this time, the voltage V1 falls below the on-threshold voltage of the switch element N4. Thus, the switch element N4 is turned off.

Therefore, while the signal transmission device 400 is started (while the enable signal ENA is maintained at the high level), the switch element N4 is turned off and the capacitor Cb is not charged by the switch element N4. During the start of the signal transmission device 400, the capacitor Cb is charged by turning on the low-side switch SWL.

The timing at which the ECU 2 raises the enable signal ENA to the high level may be as follows. For example, the ECU 2 can be configured to monitor the charge amount of the capacitor Cb (more specifically, the voltage value of the power supply voltage Vcca) and raise the enable signal ENA to the high level according to the monitoring state.

As described above, the signal transmission device 400 is not started for a predetermined period after the start of the drive circuit 500X (from the time of start until the time when the enable signal ENA rises to the high level). For this reason, the switch elements P2 and N2 remain off and the drive voltage GH is not driven. Therefore, during this period, the gate voltage of the high-side switch SWH does not rise unintentionally. Further, the capacitor Cb is charged by the pre-charge circuit 600 during this period, as described above. Therefore, even when the signal transmission device 400 is not started and the low-side switch SWL remains off, the capacitor Cb can be charged and the power supply voltage Vcca can be boosted to a sufficient voltage (a voltage at which the mirror clamp circuit 423 can operate). Therefore, during the period from the start of the drive circuit 500X until the time when the high-side chip 420 becomes operable, the high-side switch SWH can be prevented from being self-turned-on (erroneously turned-on).

Further, as described above, when the capacitor Cb is sufficiently charged, the enable signal ENA rises to the high level, and the signal transmission device 400 is started. At this time, as described above, the switch element N5 is turned on, and the capacitor Cb is no longer charged by the pre-charge circuit 600. Further, at this time, the signal transmission device 400 is started, and the switch elements P1, P2, N1, and N2 are turned on and turned off according to the combinations of the logic levels of the input signals INA and INB. Therefore, the high-side switch SWH and the low-side switch SWL are turned on and turned off. At this time (while the signal transmission device 400 is started), the capacitor Cb is charged by turning on the low-side switch SWL, and the power supply voltage Vcca is maintained at an arbitrary voltage. Therefore, even while the signal transmission device 400 is started, the mirror clamp circuit 423 can suppress the high-side switch SWH from being self-turned-on.

### <Implementation Example of Inverter 700X of Present Disclosure>

FIG. 13 is a view showing a vehicle A equipped with the motor device 800. As shown in FIG. 13, the drive circuit 500X, the inverter 700X, and the motor device 800 can be mounted on the vehicle A.

### <Modifications>

Other aspects of the present disclosure are not limited to the above-described embodiments, and various modifications can be made without departing from the spirit of the present disclosure. For example, the ECU 2 raises the enable signal ENA to a high level according to the monitoring state of the capacitor Cb, but the present disclosure is not limited thereto. For example, the ECU 2 may not monitor the state of the capacitor Cb, but may use a timer circuit to measure a time from the start of the drive circuit 500X (for example, the time when the power supply voltage Vccb rises), and raise the enable signal ENA when the measured time exceeds a predetermined time. This predetermined time is a time required for the capacitor Cb to be sufficiently charged, and is an arbitrary set time that has been determined in advance.

### <Supplementary Notes>

A drive circuit (500X) described in the present disclosure has a configuration (first configuration) that it includes: a high-side driver (420) configured to drive and control, between a high-side switch (SWH) and a low-side switch (SWL) that are bridge-connected to each other, the high-side switch (SWH) based on an external signal (ENA, INA, INB); a low-side driver (410) configured to drive and control the low-side switch (SWL) based on the external signal (ENA, INA, INB); and a bootstrap circuit (510X) configured to boost a power supply voltage (Vccb) based on the external signal (ENA, INA, INB) to generate a drive voltage (GH) for the high-side switch (SWH), wherein the bootstrap circuit (510X) includes: a capacitance circuit (Cb) configured to receive the power supply voltage (Vccb) and a reference voltage (GND1, GND3) that is lower than the power supply voltage (Vccb), to be charged according to the power supply voltage (Vccb) and the reference voltage (GND1, GND3), and to generate the drive voltage (GH); and a pre-charge circuit (600) configured to supply, based on the external signal (ENA), the reference voltage (GND1, GND3) to the capacitance circuit (Cb) when the high-side switch (SWH) and the low-side switch (SWL) are not driven, and not to supply the reference voltage (GND1, GND3) to the capacitance circuit (Cb) when the high-side switch (SWH) and the low-side switch (SWL) are driven, and wherein the capacitance circuit (Cb) receives the reference voltage (GND1, GND3) via the low-side switch (SWL) when the low-side switch (SWL) is driven and is in an on state, and receives the reference voltage (GND1, GND3) via the pre-charge circuit (600) when the low-side switch (SWL) is not driven.

The drive circuit (500X) of the first configuration may have a configuration (second configuration) that the capacitance circuit (Cb) has a capacitor (Cb) having a first terminal connected to an application terminal of the power supply voltage (Vccb), and a second terminal to which the reference voltage (GND1, GND3) is supplied, the capacitor (Cb) being configured to be charged according to a voltage difference between the power supply voltage (Vccb) and the reference voltage (GND1, GND3), and the pre-charge circuit (600) brings the second terminal and an application terminal of the reference voltage (GND1, GND3) into a conductive state via the pre-charge circuit (600) itself when the high-side switch (SWH) and the low-side switch (SWL) are not driven, and cancels the conductive state between the second terminal and the application terminal of the reference voltage (GND1, GND3) via the pre-charge circuit (600) itself when the high-side switch (SWH) and the low-side switch (SWL) are driven.

The drive circuit (500X) of the second configuration may have a configuration (third configuration) that the pre-charge circuit (600) includes: a pre-charge switch element (N4) connected between the second terminal and the application terminal of the reference voltage (GND1, GND3), the pre-charge switch element (N4) being configured to bring the second terminal and the application terminal of the reference voltage (GND1, GND3) into a conductive state in an on state; and a control switch element (N5) connected to an output terminal of the external signal (ENA), the application terminal of the power supply voltage (Vccb), the application terminal of the reference voltage (GND1, GND3), and a control terminal of the pre-charge switch element (N4), the control switch element (N5) being configured to supply, based on the external signal (ENA), either the power supply voltage (Vccb) or the reference voltage (GND1, GND3) to the control terminal according to whether or not the high-side switch (SWH) and the low-side switch (SWL) are driven to drive and control the pre-charge switch element (N4).

The drive circuit (500X) of the third configuration may have a configuration (fourth configuration) that the control switch element (N5) supplies the power supply voltage (Vccb) to the control terminal to turn on the pre-charge switch element (N4) when the high-side switch (SWH) and the low-side switch (SWL) are not driven, and supplies the reference voltage (GND1, GND3) to the control terminal to turn off the pre-charge switch element (N4) when the high-side switch (SWH) and the low-side switch (WSL) are driven.

The drive circuit (500X) of any one of the first to fourth configurations may have a configuration (fifth configuration) that the high-side driver (420) is an integrated chip.

The drive circuit (500X) of any one of the first to fifth configurations may have a configuration (sixth configuration) that the low-side driver (410) is an integrated chip.

The drive circuit (500X) of the sixth configuration may have a configuration (seventh configuration) that the pre-charge circuit (600) is integrated in the low-side driver (410).

The drive circuit (500X) of any one of the fifth to seventh configurations may have a configuration (eighth configuration) that it further includes an isolation circuit (430) configured to transmit signals between the high-side driver (420) and the low-side driver (410) while isolating the high-side driver (420) and the low-side driver (410) from each other.

An inverter (700X) described in the present disclosure has a configuration (ninth configuration) that includes: the drive circuit (500X) of any one of the first to eighth configurations; and a switch output stage including the high-side switch (SWH) and the low-side switch (SWL) that are bridge-connected to each other, the switch output stage being configured to receive a DC input voltage (VD1) and output an AC output voltage (Vout).

The inverter (700X) of the ninth configuration may have a configuration (tenth configuration) that the low-side switch (SWL) is connected between the capacitance circuit (Cb) and the application terminal of the reference voltage (GND1, GND3), brings the capacitance circuit (Cb) and the application terminal of the reference voltage (GND1, GND3) into a conductive state via the low-side switch (SWL) itself in an on state, and cancels the conductive state between the capacitance circuit (Cb) and the application terminal of the reference voltage (GND1, GND3) via the low-side switch (SWL) itself in an off state.

An electronic apparatus (800) disclosed in the present disclosure has a configuration (eleventh configuration) that includes the inverter (700X) of the ninth or tenth configuration.

A vehicle (A) disclosed in the present disclosure has a configuration (twelfth configuration) that includes the electronic apparatus (800) of the eleventh configuration.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A drive circuit comprising:
a high-side driver configured to drive and control, between a high-side switch and a low-side switch that are bridge-connected to each other, the high-side switch based on an external signal;
a low-side driver configured to drive and control the low-side switch based on the external signal; and
a bootstrap circuit configured to boost a power supply voltage based on the external signal to generate a drive voltage for the high-side switch,
wherein the bootstrap circuit includes:
a capacitance circuit configured to receive the power supply voltage and a reference voltage that is lower than the power supply voltage, to be charged according to the power supply voltage and the reference voltage, and to generate the drive voltage; and
a pre-charge circuit configured to supply, based on the external signal, the reference voltage to the capacitance circuit when the high-side switch and the low-side switch are not driven, and not to supply the reference voltage to the capacitance circuit when the high-side switch and the low-side switch are driven, and
wherein the capacitance circuit receives the reference voltage via the low-side switch when the low-side switch is driven and is in an on state, and receives the reference voltage via the pre-charge circuit when the low-side switch is not driven.

2. The drive circuit of claim 1, wherein the capacitance circuit has a capacitor having a first terminal connected to an application terminal of the power supply voltage, and a second terminal to which the reference voltage is supplied, the capacitor being configured to be charged according to a voltage difference between the power supply voltage and the reference voltage, and
wherein the pre-charge circuit brings the second terminal and an application terminal of the reference voltage into a conductive state via the pre-charge circuit itself when the high-side switch and the low-side switch are not driven, and cancels the conductive state between the second terminal and the application terminal of the reference voltage via the pre-charge circuit itself when the high-side switch and the low-side switch are driven.

3. The drive circuit of claim 2, wherein the pre-charge circuit includes:
a pre-charge switch element connected between the second terminal and the application terminal of the reference voltage, the pre-charge switch element being configured to bring the second terminal and the application terminal of the reference voltage into a conductive state in an on state; and
a control switch element connected to an output terminal of the external signal, the application terminal of the power supply voltage, the application terminal of the reference voltage, and a control terminal of the pre-charge switch element, the control switch element being configured to supply, based on the external signal, either the power supply voltage or the reference voltage to the control terminal according to whether or not the high-side switch and the low-side switch are driven to drive and control the pre-charge switch element.

4. The drive circuit of claim 3, wherein the control switch element supplies the power supply voltage to the control terminal to turn on the pre-charge switch element when the high-side switch and the low-side switch are not driven, and supplies the reference voltage to the control terminal to turn off the pre-charge switch element when the high-side switch and the low-side switch are driven.

5. The drive circuit of claim 1, wherein the high-side driver is an integrated chip.

6. The drive circuit of claim 5, wherein the low-side driver is an integrated chip.

7. The drive circuit of claim 6, wherein the pre-charge circuit is integrated in the low-side driver.

8. The drive circuit of claim 6, further comprising an isolation circuit configured to transmit signals between the high-side driver and the low-side driver while isolating the high-side driver and the low-side driver from each other.

9. An inverter comprising:
the drive circuit of claim 1; and
a switch output stage including the high-side switch and the low-side switch that are bridge-connected to each other, the switch output stage being configured to receive a direct current (DC) input voltage and output an alternate current (AC) output voltage.

10. The inverter of claim 9, wherein the low-side switch is connected between the capacitance circuit and an application terminal of the reference voltage, brings the capacitance circuit and the application terminal of the reference voltage into a conductive state via the low-side switch itself in an on state, and cancels the conductive state between the capacitance circuit and the application terminal of the reference voltage via the low-side switch itself in an off state.

11. An electronic apparatus comprising the inverter of claim 9.

12. A vehicle comprising the electronic apparatus of claim 11.
